(19) United States
(12) Patent Application Publication
(10) Pub. No.: US 2015/0014029 A1
(43) Pub. Date: Jan. 15, 2015

(54) PHOTOSENSITIVE COMPOSITION, HARDENED COATING FILMS THEREFROM, AND PRINTED WIRING BOARDS USING SAME

(71) Applicant: Hiroshi Iwayama, Kasugai-shi, Aichi (JP)

(72) Inventors: Gento Iwayama, Saitama (JP); Masao Arima, Kawagoe-shi (JP)

(73) Assignee: Taiyo Ink MFG. Co. Ltd, Saitama (JP)

(21) Appl. No.: 14/110,539

(22) PCT Filed: Apr. 4, 2012
(86) PCT No.: PCT/JP2012/059240

§ 371 Date: Feb. 3, 2014

(30) Foreign Application Priority Data
Apr. 8, 2011 (JP) 2011 086807

(51) Int. Cl. G03F 7/031; H05K 1/09; H05K 1/03; G03F 7/20

(52) U.S. Cl. CPC G03F 7/031; G03F 7/20; H05K 1/09; H05K 1/03
USPC 174/257; 430/281.1; 430/325

(57) ABSTRACT

Provided is a photosensitive composition, which comprises a carboxyl group-containing resin, a photopolymerization initiator, a photosensitive acrylate compound and a filler, wherein the filler has a refractive index of 1.5 to 1.6 and a dry coating film of the photosensitive composition shows an absorbance of at least either 0.01 to 0.2 at a wavelength of 365 nm or 0.01 to 0.2 at a wavelength of 405 nm per thickness of 25 μm. The content of the filler is preferably 20 to 60 wt % with respect to the total amount of the composition. This photosensitive composition can be advantageously used as a plating resist of a printed wiring board or a solder resist and is useful particularly in the formation of a very finely patterned resist film having a high aspect ratio.

### TECHNICAL FIELD

The present invention relates to a photosensitive composition, a cured coating film of the same and a printed wiring board of the same. More particularly, the present invention relates to a photosensitive composition which is required for producing a printed wiring board having a high aspect and a thick-film circuit pattern.

### BACKGROUND ART

In printed wiring board for automobiles and high-power LED-equipped printed wiring boards, because of the necessity for allowing a large current to flow therethrough and the necessity for heat releasability, it is required that the circuit have a high aspect and be made thicker.

Conventionally, as a method of forming a circuit pattern on a printed wiring board, a subtractive method is known. In this method, first, as shown in FIG. 1 (A), a photosensitive resin composition is coated and dried on a copper layer 102, which is formed on the surface of an insulating substrate 101. Then, the resultant is selectively exposed and developed by a photolithographic method to form a photosensitive resin layer 103 having a desired pattern (FIG. 1(B)). Subsequently, using the photosensitive resin layer 103 as an etching mask, the copper layer 102 is etched (FIG. 1(C)). Thereafter, the photosensitive resin layer 103 is removed with a removal solution such as caustic soda and the resulting substrate is then washed, thereby a printed substrate having a prescribed copper circuit pattern 104 on the insulating substrate 101 is obtained.

However, in cases where a circuit pattern having a large thickness of, for example, not less than 100 μm is prepared by a subtractive method, there are the following drawbacks. That is, in a subtractive method, during the etching process, etching progresses not only in the depth direction of the copper layer 102, but also in the horizontal direction as shown in FIG. 1(C); therefore, it is difficult to precisely control the resulting circuit width. Consequently, the resulting copper circuit pattern 104 has such a cross-sectional shape as shown in FIG. 1(D), making it difficult to ensure the circuit width accuracy. In addition, when a semi-cured insulating resin (prepreg) is embedded between the copper circuits after the etching, since the copper circuit has a large thickness, the semi-cured insulating resin layer is not sufficiently embedded. Moreover, also when a solder resist is applied after the etching, the substrate cannot attain flatness as shown in FIG. 2, so that there are problems that the resulting solder resist film 105 becomes extremely thin at protruding parts of the copper circuit surface and necessary coating film strength thus cannot be attained.

Meanwhile, as disclosed in Japanese Unexamined Patent Application Publication No. 2001-267724 (Patent Document 1), there is proposed a method where a groove pattern is formed with a photosensitive composition and a copper circuit pattern is formed in the groove by an additive process. This method is thought to be effective as a method of producing a flat wiring board having an ordinary circuit thickness. However, a photosensitive composition (plating resist) from which a groove pattern having a thickness of more than 100 μm can be formed is not proposed; therefore, a wiring board having a thick circuit pattern with a high aspect has not been obtained.

### RELATED ART DOCUMENTS

### Patent Document

Patent Document 1: Japanese Unexamined Patent Application Publication No. 2001-267724 (Examples, FIG. 1)

### SUMMARY OF THE INVENTION

### Problems to be Solved by the Invention

The present invention was made in view of the above-described prior art and an object of the present invention is to provide a photosensitive composition from which a thick copper circuit pattern having a high aspect can be formed on the inner and outer layers of a laminated board represented by a printed wiring board. Another object of the present invention is to provide a printed wiring board which comprises a thick copper circuit pattern having a high resolution and a high aspect produced by using the photosensitive composition.

### Means for Solving the Problems

In order to achieve the above-described objects, the present invention provides a photosensitive composition which comprises a carboxyl group-containing resin, a photopolymerization initiator, a photosensitive acrylate compound and a filler, the photosensitive composition being characterized in that the above-described filler has a refractive index of 1.5 to 1.6 and a dry coating film of the photosensitive composition shows an absorbance of at least either 0.01 to 0.2 at a wavelength of 365 nm or 0.01 to 0.2 at a wavelength of 405 nm per thickness of 25 μm.

Here, as the filler, fillers having a refractive index in the above-described range may be blended individually, or two or more thereof may be blended in combination. Further, it is also acceptable to blend a filler having a refractive index in the above-described range in combination with a filler having a refractive index outside the above-described range; however, it is required that the photosensitive composition contain a filler having a refractive index in the above-described range, and it is appropriate that the ratio of the filler having a refractive index of 1.5 to 1.6 be not less than 70 wt %, preferably not less than 85 wt %, with respect to the total amount of the fillers.

The term “refractive index” used herein refers to a value measured at 25° C. by an Abbe refractometer using sodium D line in accordance with the test method prescribed in JIS K7150. Further, the term “absorbance” refers to a value obtained by the below-described measurement method.

According to a preferred embodiment, the above-described filler contains Al and/or Mg. In addition, it is preferred that the content of the filler be 20 to 60 wt % with respect to the total amount of the composition.

Further, according to another preferred embodiment, the above-described photopolymerization initiator is an alkylphenone-based photopolymerization initiator

According to yet another preferred embodiment, the above-described photosensitive composition is a plating resist.

Further, the present invention provides a cured coating film which is obtained by forming a layer of the above-described photosensitive composition on an insulating substrate; selectively exposing and developing the layer; and, as required, heat-curing the resultant.

Still further, the present invention also provides a printed wiring board which comprises an insulating substrate; a layer of the above-described photosensitive composition which is formed on the surface of the insulating substrate and has a thickness of not less than 100 μm, on which layer a groove pattern having a minimum line of 75 μm and a minimum space of 75 μm is formed by selective exposure with a light and development; and a wire circuit which is a copper circuit pattern existing within the groove pattern of the photosensitive composition layer and formed such that the surface thereof constitutes substantially the same plane with the surface of the above-described photosensitive composition layer, preferably a wire circuit which is obtained by: forming a conductor layer on the entire surface of the groove of the above-described photosensitive composition layer and the layer formed from the photosensitive composition; further forming a copper plating layer by electrolytic copper plating such that the above-described groove is entirely filled with copper and the copper plating layer covers the layer formed from the photosensitive composition; and etching and/or polishing the resultant until the surface of the layer formed from the photosensitive composition is exposed so as to expose a copper circuit pattern on the surface.

In a preferred embodiment, the above-described photosensitive composition layer is, after pattern formation, subjected to at least one treatment selected from the group consisting of ultraviolet irradiation, heat treatment and plasma treatment so as to be provided as a resist film on which a copper plating layer can be formed by electroless copper plating.

In another preferred embodiment, the above-described resist film is formed by exposing a photosensitive resist film formed on the substrate surface to a pattern of ultraviolet light or selectively exposing the photosensitive resist film by direct drawing with an ultraviolet light, and subsequently developing the resultant to form a groove pattern in the part where a circuit is to be formed. Further, as required, the substrate on which the above-described resist film is formed has a through-hole.

Moreover, a multi-layer printed wiring board is prepared by, after the above-described step of exposing the copper circuit pattern, further forming an interlayer insulating resin layer and then a photosensitive resist film; and subsequently repeating the above-described steps of forming a resist film, a copper plating layer and a copper circuit pattern.

Furthermore, the present invention provides a printed wiring board prepared by the above-described method, which is characterized by comprising a copper circuit pattern of not less than 100 μm in thickness in a surface layer part and an insulating resin layer embedded between the patterns, the copper circuit pattern forming a flat surface with the insulating resin layer.

### Effects of the Invention

By using the photosensitive composition of the present invention, since the filler content is 20 wt % to 60 wt % with respect to the total amount of the non-volatile components contained in the composition, the composition can be easily coated at a large thickness, so that a cured coating film having improved properties in heat resistance and the like, as well as excellent properties in toughness and the like, can be obtained. In addition, in the photocurable resin composition of the present invention, by selecting a filler having a refractive index in the range of 1.50 to 1.6, a high resolution can be attained. This is believed to be because the refractive indices of the resin and filler contained in the photosensitive composition coincide with each other and halation is thereby inhibited, so that a high resolution can be attained.

Also, by using the photosensitive composition of the present invention, a patterned latent image can be formed by a direct drawing method with a light emitted from a lamp generating ultraviolet light and this patterned latent image can be developed with an aqueous alkaline solution. Before being exposed to a light, a dry coating film of the photosensitive composition shows an absorbance of 0.01 to 0.2 at a wavelength of 365 nm or 405 nm. Since a dry coating film of the photosensitive composition of the present invention shows an absorbance in the above-described range before being exposed to a light, the dry film can be suitably used in an ultraviolet direct drawing method. Further, since the dry coating film, before being exposed to a light, shows an absorbance of 0.01 to 0.2 at a wavelength of 365 nm or 405 nm, sufficient surface curability and curing depth can be attained, so that high sensitivity is realized.

By the above-described constitution, the photosensitive composition can attain sufficient surface curability and curing depth as well as high sensitivity; therefore, even on a thick film thereof having a thickness of about 100 μm or more, very fine lines having such a cross-section shown in the below-described FIG. 3(D) or FIG. 4 can be formed. By this, it became possible to form a thick copper circuit pattern having a thickness of not less than 100 μm, particularly not less than 200 μm, as well as a high aspect.

### BRIEF DESCRIPTION OF THE DRAWINGS

FIG. 1 shows partial cross-sectional views that illustrate the steps of forming a copper circuit pattern on a printed wiring board by a conventional subtractive method.

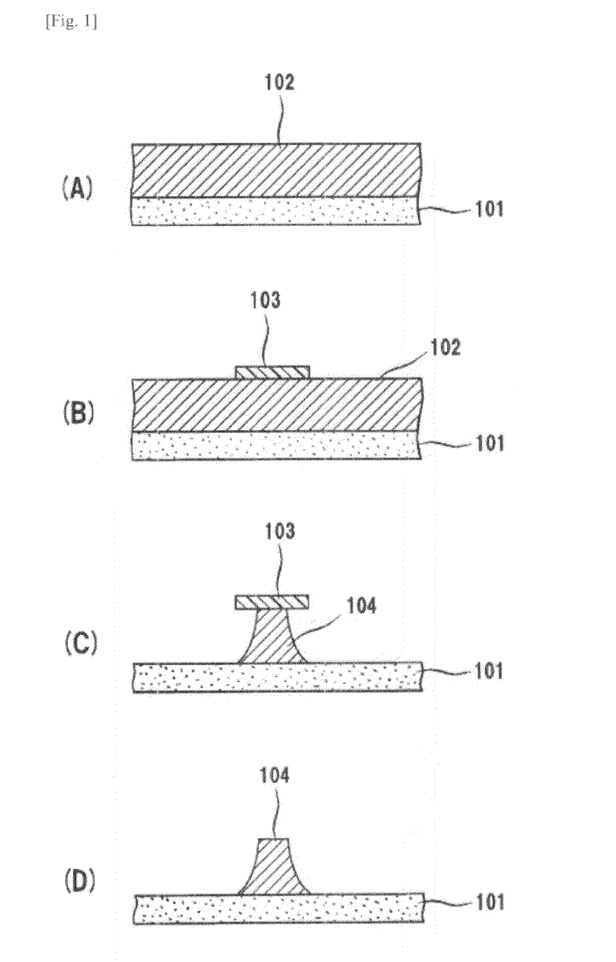

FIG. 2 is a partial cross-sectional view showing a condition in which a solder resist film is formed on the surface of a copper circuit formed by a conventional subtractive method.

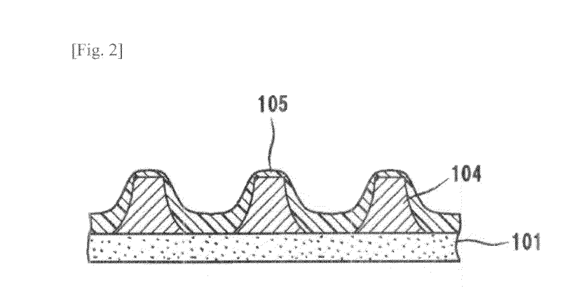

FIG. 3 shows partial cross-sectional views that illustrate one embodiment of a method of producing a printed wiring board, which comprises the steps of: forming a groove pattern on a photosensitive resist film arranged on a substrate surface using the photosensitive composition of the present invention; performing electroless copper plating and electrolytic copper plating; performing total etching or polishing; and detaching the resulting resist film.

FIG. 4 is an optical micrograph (magnification=×100) showing a condition in which only a fine copper circuit pattern was formed on a substrate after removal of a resist pattern prepared in Example 1.

### MODE FOR CARRYING OUT THE INVENTION

The present inventors intensively studied in order to solve the above-described problems and discovered that, by selecting a filler having a refractive index in the range of 1.5 to 1.6 as an indispensable component of a composition, the difference between the refractive index of a resin contained in a photosensitive composition and that of the filler can be eliminated and scattering of ultraviolet light during exposure can be inhibited, so that ultraviolet light is allowed to sufficiently reach the bottom portion of the resulting photosensitive resist and a high resolution and sufficient depth curability can be attained at the time of exposure; and that, since a dry coating film of the photosensitive composition shows an absorbance of at least either 0.01 to 0.2 at a wavelength of 365 nm or 0.01 to 0.2 at a wavelength of 405 nm per thickness of 25 μm, by reducing the absorbance of the photosensitive resist to inhibit excessive absorption of ultraviolet light by the surface portion of the photosensitive resist during exposure, ultraviolet light can be allowed to sufficiently reach the bottom portion of the photosensitive resist and this, coupled with an effect provided by selecting the above-described filler in the refractive index range of 1.5 to 1.6, allows even a thick layer of the photosensitive composition to show sufficient depth curability when exposed to a light, and a very finely patterned resist film having a thickness of not less than 100 μm, a minimum line of 75 μm, a minimum space of 75 μm and a high aspect ratio can be formed, thereby completing the present invention. It is noted here that the absorbance of a dry coating film of the photosensitive composition can be adjusted by changing the type or the amount of the photopolymerization initiator to be used and can be finely adjusted also by an addition of a coloring pigment described below.

The constituents of the photosensitive composition according to the present invention will now be described.

As the above-described carboxyl group-containing resin, for the purpose of providing alkali developability, a variety of conventionally known carboxyl group-containing resins having a carboxyl group in the molecule can be used. In particular, a carboxyl group-containing photosensitive resin having an ethylenically unsaturated double bond in the molecule is more preferred because of its photocurability and development resistance. Further, the unsaturated double bond is preferably originated from acrylic acid, methacrylic acid or a derivative thereof. Here, in cases where a carboxyl group-containing resin having no ethylenically unsaturated double bond is used alone, in order to impart the composition with photocurability, it is required that the below-described compound having at least two ethylenically unsaturated groups in the molecule, namely a photosensitive monomer, be used in combination in such an amount sufficient for photocuring.

Further, a carboxyl group-containing resin having an aromatic ring in its molecular structure is preferred since its refractive index is easily adjusted to the range of 1.50 to 1.60, and this refractive index is close to that of the above-described base (insulating substrate), so that good resolution can be attained and a cured product having good physical properties can be obtained. Examples of the carboxyl group-containing resin having an aromatic ring that can be used include styrene and derivatives thereof; indene structure; copolymers between an aromatic ring-containing (meth)acrylate such as benzyl (meth)acrylate and various (meth)acrylates; various acid-modified epoxy (meth)acrylates; and various alkylene oxide-modified phenol resins to which an acid anhydride was added.

Specific examples of the carboxyl group-containing resin include the following compounds (that may each be either an oligomer or a polymer).

(1) A carboxyl group-containing resin obtained by copolymerization of an unsaturated carboxylic acid, such as (meth)acrylic acid, and an unsaturated group-containing compound such as styrene, α-methylstyrene, a lower alkyl (meth)acrylate or isobutylene.

(2) A carboxyl group-containing urethane resin obtained by a polyaddition reaction of a diisocyanate (e.g., an aliphatic diisocyanate, a branched aliphatic diisocyanate, an alicyclic diisocyanate or an aromatic diisocyanate), a carboxyl group-containing dialcohol compound (e.g., dimethylol propionic acid or dimethylol butanoic acid) and a diol compound (e.g., a polycarbonate-based polyol, a polyether-based polyol, a polyester-based polyol, a polyolefin-based polyol, an acrylic polyol, a bisphenol A-type alkylene oxide adduct diol or a compound having a phenolic hydroxyl group and an alcoholic hydroxyl group).

(3) A terminal carboxyl group-containing urethane resin obtained by allowing an acid anhydride (e.g., phthalic anhydride, tetrahydrophthalic anhydride or hexahydrophthalic anhydride) to react with a terminal of a urethane resin produced by a polyaddition reaction of a diisocyanate compound (e.g., an aliphatic diisocyanate, a branched aliphatic diisocyanate, an alicyclic diisocyanate or an aromatic diisocyanate) and a diol compound (e.g., a polycarbonate-based polyol, a polyether-based polyol, a polyester-based polyol, a polyolefin-based polyol, an acrylic polyol, a bisphenol A-type alkylene oxide adduct diol, or a compound having a phenolic hydroxyl group and an alcoholic hydroxyl group).

(4) A carboxyl group-containing photosensitive urethane resin obtained by a polyaddition reaction of a diisocyanate; a (meth)acrylate or partial acid anhydride-modified product of a bifunctional epoxy resin, such as a bisphenol A-type epoxy resin, a hydrogenated bisphenol A-type epoxy resin, a bisphenol F-type epoxy resin, a bisphenol S-type epoxy resin, a bixylenol-type epoxy resin or a biphenol-type epoxy resin; a carboxyl group-containing dialcohol compound; and a diol compound.

(5) A carboxyl group-containing urethane resin having a (meth)acrylated terminal, which is obtained by adding a compound having one hydroxyl group and at least one (meth)acryloyl group in the molecule, such as hydroxyalkyl (meth)acrylate, during the synthesis of the resin described in the above (2) or (4).

(6) A carboxyl group-containing urethane resin having a (meth)acrylated terminal, which is obtained by adding a compound having one isocyanate group and at least one (meth)acryloyl group in the molecule, such as an equimolar reaction product of isophorone diisocyanate and pentaerythritol triacrylate, during the synthesis of the resin described in the above (2) or (4).

(7) A carboxyl group-containing photosensitive resin prepared by allowing the below-described polyfunctional (solid) epoxy resin, which has two or more functional groups, to react with (meth)acrylic acid and then adding a dibasic acid anhydride, such as phthalic anhydride, tetrahydrophthalic anhydride or hexahydrophthalic anhydride, to a hydroxyl group existing in the side chain of the resultant.

(8) A carboxyl group-containing photosensitive resin prepared by allowing a polyfunctional epoxy resin, which is obtained by further epoxidizing a hydroxyl group of the below-described bifunctional (solid) epoxy resin with epichlorohydrin, to react with (meth)acrylic acid and then adding a dibasic acid anhydride to the resulting hydroxyl group.

(9) A carboxyl group-containing photosensitive resin, which is obtained by adding a cyclic ether such as ethylene oxide and a cyclic carbonate such as propylene carbonate to a polyfunctional phenol compound such as novolac, partially esterifying the resulting hydroxyl groups with (meth)acrylic acid, and then allowing the remaining hydroxyl groups to react with a polybasic acid anhydride such as maleic anhydride, tetrahydrophthalic anhydride, trimellitic anhydride or pyromellitic dianhydride.

(10) A carboxyl group-containing photosensitive resin obtained by further adding a compound having one epoxy group and one or more (meth)acryloyl groups in the molecule, such as glycidyl (meth)acrylate or α-methylglycidyl (meth)acrylate, to any one of the resins described in the above (1) to (9).

The carboxyl group-containing resin is not restricted to those enumerated in the above, and the above-described carboxyl group-containing resins may be used individually, or a plurality thereof may be used in combination.

It is noted here that the term “(meth)acrylate” used herein is a general term for acrylates, methacrylates and mixtures thereof and this is hereinafter applicable to all similar expressions.

Since these carboxyl group-containing resins described in the above have a plurality of free carboxyl groups in the side chain of the respective backbone polymers, they can be developed with an aqueous alkaline solution.

Further, the above-described carboxyl group-containing resins have an acid value in the range of desirably 30 to 150 mg KOH/g, more preferably 40 to 110 mg KOH/g. When the acid value of the carboxyl group-containing resin is less than 30 mg KOH/g, its solubility to an aqueous alkaline solution is reduced, making it difficult to develop a coating film formed therefrom. Meanwhile, when the acid value is higher than 150 mg KOH/g, since the developer further dissolves the exposed part, the resulting lines may become excessively thin and in some cases, the exposed and non-exposed parts may be indistinctively dissolved and detached by the developer, making it difficult to form a normal resist pattern.

Further, the weight-average molecular weight of the above-described carboxyl group-containing resin varies depending on the resin skeleton; however, in general, it is generally in the range of 2,000 to 150,000, preferably in the range of 5,000 to 100,000. When the weight-average molecular weight is less than 2,000, the tack-free performance of the resulting coating film may be impaired and the moisture resistance of the coating film after being exposed to a light may become poor to cause a reduction in the film during development, which may greatly deteriorate the resolution. Meanwhile, when the weight-average molecular weight is higher than 150,000, the developing property may be markedly deteriorated and the storage stability of the composition may be impaired.

The content of such carboxyl group-containing resin is in the range of appropriately 20 to 80% by mass, preferably 30 to 60% by mass, based on the total amount of the composition. When the content of the carboxyl group-containing resin is less than the above-described range, for example, the strength of the resulting coating film may be reduced, which is not preferred. Meanwhile, when the content is higher than the above-described range, the viscosity of the composition may be increased and the coating properties and the like may be deteriorated, which are not preferred.

As the above-described photopolymerization initiator, a known and commonly used photopolymerization initiator can be used, and a known and commonly used photoinitiator aid and/or a sensitizer can also be used. Specific examples of such photopolymerization initiator, photoinitiator aid and sensitizer include alkylphenone-based compounds, benzoin compounds, acetophenone compounds, anthraquinone compounds, thioxanthone compounds, benzophenone compounds, xanthone compounds, tertiary amine compounds, oxime ester-based compounds and acylphosphine oxide-based compounds. Thereamong, from the standpoint of easily adjusting the dry coating film of the photosensitive composition to show an absorbance of at least either 0.01 to 0.2 at a wavelength of 365 nm or 0.01 to 0.2 at a wavelength of 405 nm per thickness of 25 μm, it is preferred to use an alkylphenone-based photopolymerization initiator

Further, in a plating resist, a photopolymerization initiator-originated substance contained in the resist elutes into a plating solution at the time of copper plating to cause contamination. A bifunctional or higher functional photopolymerization initiator is particularly preferred since it is easily incorporated into a resist coating film at the time of exposure and elutes into a plating solution only in a small amount.

Examples of the alkylphenone-based photopolymerization initiator include α-hydroxyalkylphenone-based compounds, α-aminoalkylphenone-based compounds and ketal compounds. Examples of commercially available α-hydroxyalkylphenone-based photopolymerization initiators include IRGACURE (registered trademark) 127, IRGACURE 184, IRGACURE 2959 and DAROCUR (registered trademark) 1173, all of which are manufactured by BASF Japan Ltd.; and ESACURE ONE manufactured by Lamberti S.p.A. Specific examples of the α-aminoacetophenone-based photopolymerization initiator include 2-methyl-1-[4-(methylthio)phenyl]-2-morpholinopropanone-1,2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-butanone and N,N-dimethylaminoacetophenone. Examples of commercially available α-aminoacetophenone-based photopolymerization initiator include IRGACURE 369, IRGACURE 379 and IRGACURE 907, all of which are manufactured by BASF Japan Ltd. Specific examples of the ketal-based photopolymerization initiators include acetophenone dimethyl ketal and benzyldimethyl ketal. Examples of commercially available products thereof include IRGACURE 651 manufactured by BASF Japan Ltd.

Further, as the photopolymerization initiator, IRGACURE 389 manufactured by BASF Japan Ltd. can also be suitably used.

Specific examples of the benzoin compounds include benzoin, benzoin methyl ether, benzoin ethyl ether and benzoin isopropyl ether.

Specific examples of the acetophenone compounds include acetophenone, 2,2-dimethoxy-2-phenyl acetophenone, 2,2-diethoxy-2-phenyl acetophenone and 1,1-dichloroacetophenone.

Specific examples of the anthraquinone compounds include 2-methylanthraquinone, 2-ethylanthraquinone, 2-t-butylanthraquinone and 1-chloroanthraquinone.

Specific examples of the thioxanthone compounds include 2,4-dimethylthioxanthone, 2,4-diethylthioxanthone, 2-chlorothioxanthone and 2,4-diisopropylthioxanthone.

Specific examples of the benzophenone compounds include benzophenone, 4-benzoyldiphenylsulfide, 4-benzoyl-4′-methyldiphenylsulfide, 4-benzoyl-4′-ethyldiphenylsulfide and 4-benzoyl-4′-propyldiphenylsulfide.

Specific examples of the tertiary amine compounds include ethanolamine compounds and compounds having a dialkylaminobenzene structure, and examples of commercially available products thereof include dialkylaminobenzophenones such as 4,4′-dimethylaminobenzophenone (NISSO CURE MABP manufactured by Nippon Soda Co., Ltd.) and 4,4′-diethylaminobenzophenone (EAB manufactured by Hodogaya Chemical Co., Ltd.); dialkylamino group-containing coumarin compounds such as 7-(diethylamino)-4-methyl-2H-1-benzopyran-2-one (7-(diethylamino)-4-methylcoumarin); ethyl-4-dimethylaminobenzoate (KAYACURE (registered trademark) EPA manufactured by Nippon Kayaku Co., Ltd.); ethyl-2-dimethylaminobenzoate (QUANTACURE DMB manufactured by International Bio-Synthetics Inc.); (n-butoxy)ethyl-4-dimethylaminobenzoate (QUANTACURE BEA manufactured by International Bio-Synthetics Inc.); isoamylethyl-p-dimethylaminobenzoate (KAYACURE DMBI manufactured by Nippon Kayaku Co., Ltd.); 2-ethylhexyl-4-dimethylaminobenzoate (ESOLOL 507 manufactured by Van Dyk Inc.); and 4,4′-diethylaminobenzophenone (EAB manufactured by Hodogaya Chemical Co., Ltd.). Thereamong, those compounds having a dialkylaminobenzene structure are preferred. Particularly preferred thereamong are dialkylaminobenzophenone compounds and dialkylamino group-containing coumarin compounds and ketocumarins that have a maximum absorption wavelength in the range of 350 to 450 nm.

As a dialkylaminobenzophenone compound, 4,4′-diethylaminobenzophenone is preferred because of its low toxicity. Since a dialkylamino group-containing coumarin compound has a maximum absorption wavelength in the ultraviolet region of 350 to 410 nm, it causes little coloration, so that not only a colorless and transparent photosensitive composition can be provided, but also a colored solder resist film which reflects the color of a coloring pigment itself can be provided by using a coloring pigment. In particular, 7-(diethylamino)-4-methyl-2H-1-benzopyran-2-one is preferred since it exhibits excellent sensitization effect against a laser light having a wavelength of 400 to 410 nm.

Examples of commercially available oxime ester-based photopolymerization initiator include CGI-325, IRGACURE OXE01 and IRGACURE OXE02, which are manufactured by BASF Japan Ltd.; and N-1919 and NCI-831, which are manufactured by ADEKA Corporation. Further, a photopolymerization initiator having two oxime ester groups in the molecule can also be suitably used, and specific examples thereof include those oxime ester compounds having a carbazole structure which are represented by the following formula:

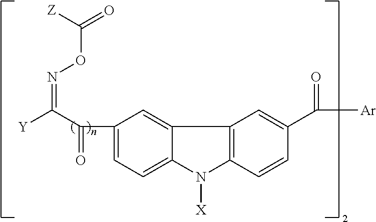

(wherein, X represents a hydrogen atom, an alkyl group having 1 to 17 carbon atoms, an alkoxy group having 1 to 8 carbon atoms, a phenyl group, a phenyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms); Y and Z each independently represent a hydrogen atom, an alkyl group having 1 to 17 carbon atoms, an alkoxy group having 1 to 8 carbon atoms, a halogen group, a phenyl group, a phenyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), an anthryl group, a pyridyl group, a benzofuryl group or a benzothienyl group; Ar represents a bond, an alkylene having 1 to 10 carbon atoms, a vinylene, a phenylene, a biphenylene, a pyridylene, a naphthylene, a thiophene, an anthrylene, a thienylene, a furylene, 2,5-pyrrole-diyl, 4,4′-stilbene-diyl or 4,2′-styrene-diyl; and n is an integer of 0 or 1).

Particularly, in the above-described formula, it is preferred that X and Y be each a methyl group or an ethyl group; Z be methyl or phenyl; n be 0; and Ar be a bond, phenylene, naphthylene, thiophene or thienylene.

Specific examples of acylphosphine oxide-based photopolymerization initiator include 2,4,6-trimethylbenzoyl diphenylphosphine oxide, bis(2,4,6-trimethylbenzoyl)-phenylphosphine oxide and bis(2,6-dimethoxybenzoyl)-2,4,4-trimethyl-pentylphosphine oxide. Examples of commercially available acylphosphine oxide-based photopolymerization initiator include LUCIRIN TPO and IRGACURE 819, which are manufactured by BASF Japan Ltd.

Representative photopolymerization initiators are enumerated in the above; however, the photopolymerization initiator is not restricted thereto and may be any photopolymerization initiator which generates radical active species when irradiated with a light and facilitates the functions of growing species thereof. Further, a known and commonly used sensitizer which does not induce radical generation by itself but has an effect of sensitizing the above-described photopolymerization initiator can also be used. The above-described photopolymerization initiators, photoinitiator aids and sensitizers can be used individually, or two or more thereof may be used in combination. Further, the amount of the photopolymerization initiator to be incorporated (or the total amount which further includes a photoinitiator aid and a sensitizer, if any) is not particularly restricted as long as the absorbance of the photosensitive composition is in the above-described range; however, in general, the higher the amount, the higher becomes the absorbance, and the less the amount, the lower becomes the absorbance. Here, the amount of the photopolymerization initiator to be blended may be appropriately adjusted at an ordinary quantitative ratio and, in general, it is appropriately in the range of 0.01 to 30 parts by mass, preferably 0.5 to 15 parts by mass, with respect to 100 parts by mass of the carboxyl group-containing resin (the total amount if two or more carboxyl group-containing resins are used; this provision applies hereinafter). When the content of the photopolymerization initiator is less than 0.01 parts by mass, the photocurability of the photosensitive composition is insufficient, so that the resulting coating film may be detached or the properties of the coating film such as chemical resistance are deteriorated, which are not preferred. Meanwhile, when the content of the photopolymerization initiator is higher than 30 parts by mass, outgas is generated and contamination and the like of plating occur, which are not preferred.

The photosensitive acrylate compound used in the photosensitive composition of the present invention is a compound which has two or more ethylenically unsaturated groups in the molecule and is photo-cured when irradiated with an active energy beam, thereby insolubilizing or assisting to insolubilize the above-described carboxyl group-containing resin to an aqueous alkaline solution. Examples of such a compound include hydroxyalkyl acrylates such as 2-hydroxyethyl acrylate and 2-hydroxypropyl acrylate; diacrylates of glycol such as ethylene glycol, methoxytetraethylene glycol, polyethylene glycol and propylene glycol; acrylamides such as N,N-dimethylacrylamide, N-methylolacrylamide and N,N-dimethylaminopropylacrylamide; aminoalkyl acrylates such as N,N-dimethylaminoethyl acrylate and N,N-dimethylaminopropyl acrylate; polyvalent acrylates of polyhydric alcohols (e.g., hexanediol, trimethylolpropane, pentaerythritol, dipentaerythritol and tris-hydroxyethyl isocyanurate) and ethylene oxide adducts, propylene oxide adducts or ε-caprolactone adducts of these polyhydric alcohols; polyvalent acrylates such as phenoxyacrylate, bisphenol A diacrylate and ethylene oxide adducts or propylene oxide adducts of these phenols; and polyvalent acrylates of glycidyl ethers such as glycerin diglycidyl ether, glycerin triglycidyl ether, trimethylolpropane triglycidyl ether and triglycidyl isocyanate. In addition to the above, examples also include acrylates and melamine acrylates that are obtained by direct acrylation or diisocyanate-mediated urethane acrylation of a polyol such as polyether polyol, polycarbonate diol, hydroxyl group-terminated polybutadiene or polyester polyol; and methacrylates corresponding to the above-described acrylates. These photosensitive acrylate compounds may be used individually, or two or more thereof may be used in combination. In particular, from the standpoints of photoreactivity and resolution, a compound having 4 to 6 ethylenically unsaturated groups in one molecule is preferred. Further, a compound having two ethylenically unsaturated groups in one molecule is also preferably used since it can contribute to an improvement in the heat resistance.

Examples of the photosensitive acrylate compound also include epoxy acrylate resins obtained by allowing a polyfunctional epoxy resin such as a cresol novolac-type epoxy resin to react with acrylic acid; and epoxy urethane acrylate compounds obtained by allowing the hydroxyl groups of the above-described epoxy acrylate resins to react with a hydroxyacrylate such as pentaerythritol triacrylate and a half urethane compound of diisocyanate such as isophorone diisocyanate. These epoxy acrylate-based resins are capable of improving the photocurability of the photosensitive composition without impairing the dryness to touch.

It is appropriate that the amount of such photosensitive acrylate compound to be blended is 1 to 100 parts by mass, more preferably 5 to 70 parts by mass, with respect to 100 parts by mass of the above-described carboxyl group-containing resin. When the amount is less than 5 parts by mass, the photocurability of the photosensitive composition is impaired, so that it becomes difficult to form a pattern by development with an alkali after irradiation with an active energy beam, which is not preferred. Meanwhile, when the amount is higher than 100 parts by mass, the solubility of the photosensitive composition to an aqueous alkaline solution is reduced to make the resulting coating film fragile, which is not preferred.

A filler is incorporated in the photosensitive composition of the present invention. It was discovered that, when the filler has a refractive index in the range of 1.5 to 1.6, scattering of ultraviolet light during exposure can be inhibited, so that ultraviolet light is allowed to sufficiently reach the bottom portion of the resulting photosensitive resist and a high resolution and sufficient depth curability can be attained at the time of exposure. As for the reason why a high resolution can be attained, it is believed to because halation can be inhibited when the carboxyl group-containing resin used for improving the heat resistance and photosensitivity, particularly carboxyl group-containing resin having an aromatic ring, has a refractive index similar to that of the filler. Further, as a result of examining the amount of the filler to be blended in detail, it was discovered that the composition can be easily coated at a large thickness and the heat resistance is improved by controlling the filler content in the range of 20 to 60 wt % with respect to the total amount of the composition. When the filler content is not in the above-described range, it is difficult to form a very finely patterned resist film having a thickness of not less than 100 μm, a minimum line of 75 μm, a minimum space of 75 μm and a high aspect ratio. Further, when the filler content is less than 20 wt %, the heat resistance of a cured product of the photosensitive composition is impaired, which is not preferred. Meanwhile, when the filler content is higher than 60 wt %, the viscosity of the composition is increased to impair the coating properties and moldability, which is not preferred. Moreover, in cases where the photosensitive composition contains two or more fillers, it is appropriate that the ratio of the filler having a refractive index of 1.5 to 1.6 be not less than 70 wt %, preferably not less than 85 wt %, with respect to the total amount of the fillers.

As the filler used in the present invention, for example, a known and commonly used inorganic filler such as talc, clay, magnesium carbonate, calcium carbonate, aluminum hydroxide, mica powder or hydrotalcite can be employed. In particular, as Al-containing fillers, hydrous kaolin clay (refractive index: 1.55 to 1.57) and gibbsite-type aluminum hydroxide (refractive index: 1.54) are preferred; as Mg-containing fillers, talc (refractive index: 1.54 to 1.59), magnesium carbonate (refractive index: 1.57 to 1.60) and mica powder (refractive index: 1.59) are preferred; and as fillers containing Mg and Al, hydrotalcite (refractive index: 1.50) and magnesium hydroxide (refractive index: 1.56 to 1.58) are preferred. Examples of the filler having a refractive index outside of the above-described range include aluminum oxide (refractive index: 1.65), barium sulfate (refractive index: 1.65), calcined kaolin clay (refractive index: 1.62) and boehmite (refractive index: 1.62 to 1.65), and these fillers may be added as required in such a range which does not adversely affect the effects of the present invention.

Further, in the photosensitive composition used in the present invention, in order to impart thereto heat resistance, a thermosetting component can be added. As the thermosetting component, a known and commonly used thermosetting resin, such as an amino resin (e.g., a melamine resin, a benzoguanamine resin, a melamine derivative or a benzoguanamine derivative), a bismaleimide compound, a benzoxazine compound, an oxazoline compound, a carbodiimide resin, a blocked isocyanate compound, a cyclocarbonate compound, a polyfunctional epoxy compound, a polyfunctional oxetane compound, a episulfide resin or a melamine derivative, can be employed. Particularly preferred thereamong is a thermosetting component having a plurality of 3-, 4- or 5-membered cyclic ether groups and/or thioether groups (hereinafter, simply referred to as “cyclic (thio)ether groups”) in one molecule, and examples thereof include polyfunctional epoxy compounds having a plurality of epoxy groups in the molecule; polyfunctional oxetane compounds having a plurality of oxetanyl groups in the molecule; and episulfide resins having a plurality of thioether groups in the molecule. The amount of the thermosetting component to be added is in the range of preferably 0.6 to 2.5 equivalents, more preferably 0.8 to 2.0 equivalents, with respect to 1 equivalent of carboxyl group in the above-described carboxyl group-containing resin.

Examples of the above-described polyfunctional epoxy compounds include, but not limited to, epoxidized vegetable oils such as ADK CIZER O-130P, ADK CIZER O-180A, ADK CIZER D-32 and ADK CIZER D-55, which are manufactured by ADEKA Corporation; bisphenol A-type epoxy resins such as jER (registered trademark) 828, jER 834, jER 1001 and jER 1004, which are manufactured by Mitsubishi Chemical Corporation, EHPE 3150 manufactured by Daicel Corporation, EPICLON (registered trademark) 840, EPICLON 850, EPICLON 1050 and EPICLON 2055, which are manufactured by DIC Corporation, EPOTOHTO (registered trademark) YD-011, YD-013, YD-127 and YD-128, which are manufactured by NIPPON STEEL &SUMIKIN CHEMICAL CO., LTD., D.E.R. 317, D.E.R. 331, D.E.R. 661 and D.E.R. 664, which are manufactured by The Dow Chemical Company, SUMI-EPDXY ESA-011, ESA-014, ELA-115 and ELA-128, which are manufactured by Sumitomo Chemical Company, Limited, and A.E.R. 330, A.E.R. 331, A.E.R. 661 and A.E.R. 664, which are manufactured by Asahi Kasei Corp. (all of the above are trade names); hydroquinone-type epoxy resin YDC-1312, bisphenol-type epoxy resin YSLV-80XY and thioether-type epoxy resin YSLV-120TE (all of which are manufactured by NIPPON STEEL &SUMIKIN CHEMICAL CO., LTD.); brominated epoxy resins such as jERYL 903 manufactured by Mitsubishi Chemical Corporation, EPICLON 152 and EPICLON 165, which are manufactured by DIC Corporation, EPOTOHTO YDB-400 and YDB-500, which are manufactured by NIPPON STEEL &SUMIKIN CHEMICAL CO., LTD., D.E.R. 542 manufactured by The Dow Chemical Company, SUMI-EPDXY ESB-400 and ESB-700, which are manufactured by Sumitomo Chemical Company, Limited, and A.E.R. 711 and A.E.R. 714, which are manufactured by ADEKA Corporation (all of the above are trade names); novolac-type epoxy resins such as jER 152 and jER 154, which are manufactured by Mitsubishi Chemical Corporation, D.E.N. 431 and D.E.N. 438, which are manufactured by The Dow Chemical Company, EPICLON N-730, EPICLON N-770 and EPICLON N-865, which are manufactured by DIC Corporation, EPOTOHTO YDCN-701 and YDCN-704, which are manufactured by NIPPON STEEL &SUMIKIN CHEMICAL CO., LTD., EPPN (registered trademark) 201, EOCN (registered trademark) 1025, EOCN-1020, EOCN-104S and RE-306, which are manufactured by Nippon Kayaku Co., Ltd., SUMI-EPDXY ESCN-195X and ESCN-220, which are manufactured by Sumitomo Chemical Company, Limited, and A.E.R.ECN-235 and ECN-299, which are manufactured by Asahi Kasei Corp., (all of the above are trade names); biphenol novolac-type epoxy resins such as NC-3000 and NC-3100, which are manufactured by Nippon Kayaku Co., Ltd.; bisphenol F-type epoxy resins such as EPICLON 830 manufactured by DIC Corporation, jER807 manufactured by Mitsubishi Chemical Corporation, and EPOTOHTO YDF-170, YDF-175 and YDF-2004 which are manufactured by NIPPON STEEL &SUMIKIN CHEMICAL CO., LTD. (all of the above are trade names); hydrogenated bisphenol A-type epoxy resins such as EPOTOHTO ST-2004, ST-2007 and ST-3000 (trade names) which are manufactured by NIPPON STEEL &SUMIKIN CHEMICAL CO., LTD.; glycidyl amine-type epoxy resins such as jER 604 manufactured by Mitsubishi Chemical Corporation, EPOTOHTO YH-434 manufactured by NIPPON STEEL &SUMIKIN CHEMICAL CO., LTD. and SUMI-EPDXY ELM-120 manufactured by Sumitomo Chemical Company, Limited (all of the above are trade names); hydantoin-type epoxy resins; alicyclic epoxy resins such as CELLOXIDE (registered trademark) 2021 manufactured by Daicel Corporation; trihydroxyphenyl methane-type epoxy resins such as YL-933 manufactured by Mitsubishi Chemical Corporation, and T.E.N., EPPN-501 and EPPN-502, which are manufactured by The Dow Chemical Company (all of the above are trade names); bixylenol-type or biphenol-type epoxy resins and mixtures thereof, such as YL-6056, YX-4000 and YL-6121 (all of which are trade names) manufactured by Mitsubishi Chemical Corporation; bisphenol S-type epoxy resins such as EBPS-200 manufactured by Nippon Kayaku Co., Ltd., EPX-30 manufactured by ADEKA Corporation and EXA-1514 (trade name) manufactured by DIC Corporation; bisphenol A novolac-type epoxy resins such as jER157S (trade name) manufactured by Mitsubishi Chemical Corporation; tetraphenylolethane-type epoxy resins such as jERYL-931 manufactured by Mitsubishi Chemical Corporation; heterocyclic epoxy resins such as TEPIC (registered trademark) manufactured by Nissan Chemical Industries, Ltd.; diglycidyl phthalate resins such as BLEMMER (registered trademark) DGT manufactured by NOF Corporation; tetraglycidyl xylenoylethane resins such as ZX-1063 manufactured by NIPPON STEEL &SUMIKIN CHEMICAL CO., LTD.; naphthalene group-containing epoxy resins such as ESN-190 and ESN-360 which are manufactured by NIPPON STEEL &SUMIKIN CHEMICAL CO., LTD., and HP-4032, EXA-4750 and EXA-4700 which are manufactured by DIC Corporation; epoxy resins having a dicyclopentadiene skeleton, such as HP-7200 and HP-7200H manufactured by DIC Corporation; glycidyl methacrylate copolymer-based epoxy resins such as CP-50S and CP-50M manufactured by NOF Corporation; cyclohexylmaleimide-glycidyl methacrylate copolymer epoxy resins; epoxy-modified polybutadiene rubber derivatives (such as PB-3600 manufactured by Daicel Corporation); and CTBN-modified epoxy resins (such as YR-102 and YR-450 manufactured by NIPPON STEEL &SUMIKIN CHEMICAL CO., LTD.). These epoxy resins may be used individually, or two or more thereof may be used in combination. Thereamong, novolac-type epoxy resins, bixylenol-type epoxy resins, biphenol-type epoxy resins, biphenol novolac-type epoxy resins, naphthalene-type epoxy resins and mixtures thereof are particularly preferred.

Examples of the above-described polyfunctional oxetane compounds include polyfunctional oxetanes such as bis[(3-methyl-3-oxcetanylmethoxy)methyl]ether, bis[(3-ethyl-3-oxcetanylmethoxy)methyl]ether, 1,4-bis[(3-methyl-3-oxcetanylmethoxy)methyl]benzene, 1,4-bis[(3-ethyl-3-oxcetanylmethoxy)methyl]benzene, (3-methyl-3-oxcetanyl)methyl acrylate, (3-ethyl-3-oxcetanyl)methyl acrylate, (3-methyl-3-oxcetanyl)methyl methacrylate, (3-ethyl-3-oxcetanyl)methyl methacrylate, and oligomers and copolymers thereof; and etherification products of an oxetane alcohol and a resin having a hydroxyl group such as a novolac resin, a poly(p-hydroxystyrene), a cardo-type bisphenol, a calixarene, a calix resorcin arene or a silsesquioxane. In addition, examples of the polyfunctional oxetane compounds also include copolymers of an unsaturated monomer having an oxetane ring and an alkyl (meth)acrylate.

Examples of the compounds having a plurality of cyclic thioether groups in the molecule include bisphenol A-type episulfide resin YL7000 manufactured by Mitsubishi Chemical Corporation. Further, for example, an episulfide resin prepared by the same synthesis method, in which an oxygen atom of an epoxy group of a novolac-type epoxy resin is substituted with a sulfur atom, can also be used.

Further, to the photosensitive composition of the present invention, an elastomer having a functional group may be added. An addition of an elastomer having a functional group has been confirmed to improve the coating properties and observed to have an effect of improving the coating film strength as well. Examples of such elastomer having a functional group include, as trade names, R-45HT and Poly bd HTP-9 (both of which are manufactured by Idemitsu Kosan Co., Ltd.); EPOLEAD PB3600 (manufactured by Daicel Corporation); DENAREX R-45EPT (manufactured by Nagase ChemteX Corporation); and RICON 130, RICON 131, RICON 134, RICON 142, RICON 150, RICON 152, RICON 153, RICON 154, RICON 156, RICON 157, RICON 100, RICON 181, RICON 184, RICON 130MA8, RICON 130MA13, RICON 130MA20, RICON 131MA5, RICON 131MA10, RICON 131MA17, RICON 131MA20, RICON 184MA6 and RICON 156MA17 (all of which are manufactured by Sartomer Co.). As the elastomer having a functional group, a polyester-based elastomer, a polyurethane-based elastomer, a polyester urethane-based elastomer, a polyamide-based elastomer, a polyester amide-based elastomer, an acrylic elastomer or an olefin-based elastomer can also be employed. In addition, for example, a resin obtained by modifying some or all of epoxy groups contained in an epoxy resin having various skeletons with a butadiene-acrylonitrile rubber whose terminals are both modified with carboxylic acid can also be employed. Moreover, for example, an epoxy-containing polybutadiene-based elastomer, an acryl-containing polybutadiene-based elastomer, a hydroxyl group-containing polybutadiene-based elastomer or a hydroxyl group-containing isoprene-based elastomer can be employed as well. The elastomer to be added is preferably in the range of 3 to 124 parts by mass with respect to 100 parts by mass of the carboxyl group-containing resin. Further, the above-described elastomers may be used individually, or two or more thereof may be used in combination.

Further, examples of the amino resin (e.g., a melamine resin or a benzoguanamine resin) used as the thermosetting component include methylol melamine compounds, methylol benzoguanamine compounds, methylol glycoluril compounds and methylol urea compounds. Moreover, alkoxymethylated melamine compounds, alkoxymethylated benzoguanamine compounds, alkoxymethylated glycoluril compounds and alkoxymethylated urea compounds can be obtained by converting the methylol group of the respective methylol melamine compounds, methylol benzoguanamine compounds, methylol glycoluril compounds and methylol urea compounds into an alkoxymethyl group. The type of this alkoxymethyl group is not particularly restricted and examples thereof include methoxymethyl group, ethoxymethyl group, propoxymethyl group and butoxymethyl group. In particular, a melamine derivative having a formalin concentration of not higher than 0.2%, which is not harmful to human body and environment, is preferred.

Examples of commercially products of the above-described thermosetting components include CYMEL (registered trademark) 300, 301, 303, 370, 325, 327, 701, 266, 267, 238, 1141, 272, 202, 1156, 1158, 1123, 1170, 1174, UFR 65 and 300 (all of which are manufactured by Cytec Industries Inc.); and NIKALAC Mx-750, Mx-032, Mx-270, Mx-280, Mx-290, Mx-706, Mx-708, Mx-40, Mx-31, Ms-11, Mw-30, Mw-30HM, Mw-390, Mw-100LM and Mw-750LM (all of which are manufactured by Sanwa Chemical Co., Ltd.). These thermosetting components may be used individually, or two or more thereof may be used in combination.

In the photosensitive composition of the present invention, a compound having a plurality of isocyanate groups or blocked isocyanate groups in one molecule may also be incorporated. Examples of such a compound having a plurality of isocyanate groups or blocked isocyanate groups in one molecule include polyisocyanate compounds and blocked isocyanate compounds. Here, the term “blocked isocyanate group” refers to a group in which isocyanate group is protected by a reaction with a blocking agent and thus temporarily inactivated. When heated to a prescribed temperature, the blocking agent dissociates to yield an isocyanate group. An addition of the above-described polyisocyanate compound or blocked isocyanate compound has been confirmed to improve the curability of the photosensitive composition and the toughness of the resulting cured product.

As the polyisocyanate compound, for example, an aromatic polyisocyanate, an aliphatic polyisocyanate or an alicyclic polyisocyanate may be employed.

Specific examples of the aromatic polyisocyanate include 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate and 2,4-tolylene dimer.

Specific examples of the aliphatic polyisocyanate include tetramethylene diisocyanate, hexamethylene diisocyanate, methylene diisocyanate, trimethylhexamethylene diisocyanate, 4,4-methylenebis(cyclohexylisocyanate) and isophorone diisocyanate.

Specific examples of the alicyclic polyisocyanate include bicycloheptane triisocyanate, as well as adducts, biurets and isocyanurates of the above-described isocyanate compounds.

As the blocked isocyanate compound, a product obtained by an addition reaction between an isocyanate compound and an isocyanate blocking agent may be employed. Examples of an isocyanate compound which can react with a blocking agent include the above-described polyisocyanate compounds.

Examples of the isocyanate blocking agent include phenolic blocking agents such as phenol, cresol, xylenol, chlorophenol and ethylphenol; lactam-based blocking agents such as ε-caprolactam, δ-valerolactam, γ-butyrolactam and β-propiolactam; activated methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate and ethyl lactate; oxime-based blocking agents such as formaldehyde oxime, acetaldoxime, acetoxime, methylethyl ketoxime, diacetyl monooxime and cyclohexane oxime; mercaptan-based blocking agents such as butylmercaptan, hexylmercaptan, t-butylmercaptan, thiophenol, methylthiophenol and ethylthiophenol; acid amid-based blocking agents such as acetic acid amide and benzamide; imide-based blocking agents such as succinic acid imide and maleic acid imide; amine-based blocking agents such as xylidine, aniline, butylamine and dibutylamine; imidazole-based blocking agents such as imidazole and 2-ethylimidazole; and imine-based blocking agents such as methyleneimine and propyleneimine.

The blocked isocyanate compound may be of a commercially available product and examples thereof include SUMIDUR (registered trademark) BL-3175, BL-4165, BL-1100 and BL-1265, DESMODUR (registered trademark) TPLS-2957, TPLS-2062, TPLS-2078 and TPLS-2117 and DESMOTHERM (registered trademark) 2170 and 2265 (all of which are manufactured by Sumika Bayer Urethane Co., Ltd.); CORONATE (registered trademark) 2512, 2513 and 2520 (all of which are manufactured by Nippon Polyurethane Industry Co., Ltd.); B-830, B-815, B-846, B-870, B-874 and B-882 (all of which are manufactured by Mitsui Mitsui Chemicals, Inc.); and TPA-B80E, 17B-60PX and E402-B80T (all of which are manufactured by Asahi Kasei Chemicals Corp.). It is noted here that SUMIDUR BL-3175 and BL-4265 are produced by using methylethyl oxime as a blocking agent. The above-described compounds having a plurality of isocyanate groups or blocked isocyanate groups in one molecule may be used individually, or two or more thereof may be used in combination.

The amount of such compound(s) having a plurality of isocyanate groups or blocked isocyanate groups in one molecule is preferably 1 to 100 parts by mass with respect to 100 parts by mass of the carboxyl group-containing resin. When the amount is less than 1 part by mass, a coating film having sufficient toughness cannot be obtained. Meanwhile, when the amount is greater than 100 parts by mass, the storage stability is deteriorated. The amount of the compound(s) having a plurality of isocyanate groups or blocked isocyanate groups in one molecule is more preferably 2 to 70 parts by mass.

In cases where a thermosetting component having a plurality of cyclic (thio)ether groups in the molecule is used, it is preferred that a heat-curing catalyst be incorporated as well. Examples of the heat-curing catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine and 4-methyl-N,N-dimethylbenzylamine; hydrazine compounds such as adipic acid dihydrazide and sebacic acid dihydrazide; and phosphorus compounds such as triphenyl phosphine. Further, examples of commercially available heat-curing catalyst include 2MZ-A, 2MZ-OK, 2PHZ, 2P4BHZ and 2P4MHZ (all of which are imidazole-based compounds; trade names), which are manufactured by Shikoku Chemicals Corporation; and U-CAT (registered trademark) 3503N and U-CAT 3502T (both of which are blocked isocyanate compounds of dimethylamine; trade names) and DBU, DBN, U-CAT SA102 and U-CAT 5002 (all of which are a bicyclic amidine compound or a salt thereof), which are manufactured by San-Apro Ltd. The heat-curing catalyst is not particularly restricted to these compounds and it may be a heat-curing catalyst of an epoxy resin or an oxetane compound, or any compound which facilitates the reaction of an epoxy group and/or an oxetanyl group with a carboxyl group. Such heat-curing catalysts may be used individually, or two or more thereof may be used in combination. Further, an s-triazine derivative, such as guanamine, acetoguanamine, benzoguanamine, melamine, 2,4-diamino-6-methacryloyloxyethyl-s-triazine, 2-vinyl-2,4-diamino-s-triazine, 2-vinyl-4,6-diamino-s-triazine.socyanuric acid adduct or 2,4-diamino-6-methacryloyloxyethyl-s-triazine.isocyanuric acid adduct, can also be used. Preferably, such compound which also functions as an adhesion-imparting agent is used in combination with a heat-curing catalyst.

The amount of the heat-curing catalyst(s) to be incorporated is sufficient at an ordinary quantitative ratio and, for example, it is preferably 0.1 to 20 parts by mass, more preferably 0.5 to 15.0 parts by mass, with respect to 100 parts by mass of the carboxyl group-containing resin or the thermosetting component having a plurality of cyclic (thio)ether groups in the molecule.

Further, in the curable resin composition of the present invention, a coloring agent may be blended as well. As the coloring agent, a known coloring agent of red, blue, green, yellow, white, black or the like can be used, and it may be any of a pigment, a stain or a dye. Specific examples of the coloring agent include those assigned with the following Color Index numbers (C.I.; issued by The Society of Dyers and Colourists). Here, from the standpoint of reducing the environmental stress and the effects on human body, it is preferred that the coloring agent contain no halogen.

### Red Coloring Agent:

Examples of red coloring agent include monoazo-type, disazo-type, azo lake-type, benzimidazolone-type, perylene-type, diketopyrrolopyrrole-type, condensed azo-type, anthraquinone-type and quinacridone-type red coloring agents, and specific examples thereof include the followings.

Monoazo-type: Pigment Reds 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268 and 269

Disazo-type: Pigment Reds 37, 38 and 41

Monoazo lake-type: Pigment Reds 48:1, 48:2, 48:3, 48:4, 49:1, 49:2, 50:1, 52:1, 52:2, 53:1, 53:2, 57:1, 58:4, 63:1, 63:2, 64:1 and 68

Benzimidazolone-type: Pigment Red 171, Pigment Red 175, Pigment Red 176, Pigment Red 185 and Pigment Red 208

Perylene-type: Solvent Red 135, Solvent Red 179, Pigment Red 123, Pigment Red 149, Pigment Red 166, Pigment Red 178, Pigment Red 179, Pigment Red 190, Pigment Red 194 and Pigment Red 224

Diketopyrrolopyrrole-type: Pigment Red 254, Pigment Red 255, Pigment Red 264, Pigment Red 270 and Pigment Red 272

Condensed azo-type: Pigment Red 220, Pigment Red 144, Pigment Red 166, Pigment Red 214, Pigment Red 220, Pigment Red 221 and Pigment Red 242

Anthraquinone-type: Pigment Red 168, Pigment Red 177, Pigment Red 216, Solvent Red 149, Solvent Red 150, Solvent Red 52 and Solvent Red 207

Quinacridone-type: Pigment Red 122, Pigment Red 202, Pigment Red 206, Pigment Red 207 and Pigment Red 209 Blue Coloring Agent:

Examples of blue coloring agent include phthalocyanine-type and anthraquinone-type blue coloring agents, and examples of pigment-type blue coloring agent include those compounds that are classified into pigment. Specific examples thereof include Pigment Blue 15, Pigment Blue 15:1, Pigment Blue 15:2, Pigment Blue 15:3, Pigment Blue 15:4, Pigment Blue 15:6, Pigment Blue 16 and Pigment Blue 60.

As a stain-type blue coloring agent, for example, Solvent Blue 35, Solvent Blue 63, Solvent Blue 68, Solvent Blue 70, Solvent Blue 83, Solvent Blue 87, Solvent Blue 94, Solvent Blue 97, Solvent Blue 122, Solvent Blue 136, Solvent Blue 67 and Solvent Blue 70 can be used. In addition to the above-described ones, a metal-substituted or unsubstituted phthalocyanine compound can be used as well.

### Green Coloring Agent:

Similarly, examples of green coloring agent include phthalocyanine-type, anthraquinone-type and perylene-type green coloring agents and specifically, for example, Pigment Green 7, Pigment Green 36, Solvent Green 3, Solvent Green 5, Solvent Green 20 and Solvent Green 28 can be used. In addition to the above-described ones, a metal-substituted or unsubstituted phthalocyanine compound can be used as well.

### Yellow Coloring Agent:

Examples of yellow coloring agent include monoazo-type, disazo-type, condensed azo-type, benzimidazolone-type, isoindolinone-type and anthraquinone-type yellow coloring agents and specific examples thereof include the followings.

Anthraquinone-type: Solvent Yellow 163, Pigment Yellow 24, Pigment Yellow 108, Pigment Yellow 193, Pigment Yellow 147, Pigment Yellow 199 and Pigment Yellow 202

Isoindolinone-type: Pigment Yellow 110, Pigment Yellow 109, Pigment Yellow 139, Pigment Yellow 179 and Pigment Yellow 185

Condensed azo-type: Pigment Yellow 93, Pigment Yellow 94, Pigment Yellow 95, Pigment Yellow 128, Pigment Yellow 155, Pigment Yellow 166 and Pigment Yellow 180

Benzimidazolone-type: Pigment Yellow 120, Pigment Yellow 151, Pigment Yellow 154, Pigment Yellow 156, Pigment Yellow 175 and Pigment Yellow 181

Monoazo-type: Pigment Yellows 1, 2, 3, 4, 5, 6, 9, 10, 12, 61, 62, 62:1, 65, 73, 74, 75, 97, 100, 104, 105, 111, 116, 167, 168, 169, 182 and 183

Disazo-type: Pigment Yellows 12, 13, 14, 16, 17, 55, 63, 81, 83, 87, 126, 127, 152, 170, 172, 174, 176, 188, and 198.

In addition to the above, in order to adjust the color tone, for example, a violet, orange, brown and/or black coloring agent(s) may also be added. Specific examples of such coloring agent include Pigment Violets 19, 23, 29, 32, 36, 38 and 42, Solvent Violets 13 and 36, C.I. Pigment Orange 1, C.I. Pigment Orange 5, C.I. Pigment Orange 13, C.I. Pigment Orange 14, C.I. Pigment Orange 16, C.I. Pigment Orange 17, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 51, C.I. Pigment Orange 61, C.I. Pigment Orange 63, C.I. Pigment Orange 64, C.I. Pigment Orange 71, C.I. Pigment Orange 73, C.I. Pigment Brown 23, C.I. Pigment Brown 25, C.I. Pigment Black 1 and C.I. Pigment Black 7.

The above-described coloring agents may be blended as appropriate and the content thereof is preferably not higher than 10 parts by mass, more preferably 0.1 to 5 parts by mass, with respect to 100 parts by mass of the carboxyl group-containing resin or the thermosetting component.

In addition, in the photosensitive composition of the present invention, an organic solvent may be used for the purpose of synthesizing the above-described carboxyl group-containing resin, preparing the composition or adjusting the viscosity for coating the composition onto a substrate or a carrier film.

Examples of such an organic solvent include ketones, aromatic hydrocarbons, glycol ethers, glycol ether acetates, esters, alcohols, aliphatic hydrocarbons and petroleum-based solvents. More specific examples thereof include ketones such as methyl ethyl ketone and cyclohexanone; aromatic hydrocarbons such as toluene, xylene and tetramethylbenzene; glycol ethers such as cellosolve, methylcellosolve, butylcellosolve, carbitol, methylcarbitol, butylcarbitol, propylene glycol monomethyl ether, dipropylene glycol monomethyl ether, dipropylene glycol diethyl ether and triethylene glycol monoethyl ether; esters such as ethyl acetate, butyl acetate, dipropylene glycol methyl ether acetate, propylene glycol methyl ether acetate, propylene glycol ethyl ether acetate and propylene glycol butyl ether acetate; alcohols such as ethanol, propanol, ethylene glycol and propylene glycol; aliphatic hydrocarbons such as octane and decane; and petroleum-based solvents such as petroleum ether, petroleum naphtha, hydrogenated petroleum naphtha and solvent naphtha. These organic solvents may be used individually, or two or more thereof may be used in the form of a mixture.

In the photosensitive composition of the present invention, in order to inhibit oxidation thereof, an antioxidant(s) such as (1) a radical scavenger which deactivates generated radicals and/or (2) a peroxide decomposer which decomposes generated peroxide into a non-toxic substance and prevents generation of new radicals may be incorporated.

Examples of the antioxidant which functions as a radical scavenger include phenolic compounds such as hydroquinone, 4-t-butylcatechol, 2-t-butylhydroquinone, hydroquinone monomethyl ether, 2,6-di-t-butyl-p-cresol, 2,2-methylene-bis(4-methyl-6-t-butylphenol), 1,1,3-tris(2-methyl-4-hydroxy-5-t-butylphenyl)butane, 1,3,5-trimethyl-2,4,6-tris(3,5-di-t-butyl-4-hydroxybenzyl)benzene and 1,3,5-tris(3′,5′-di-t-butyl-4-hydroxybenzyl)-s-triazine-2,4,6-(1H,3H,5H)trione; quinone-based compounds such as metaquinone and benzoquinone; and amine-based compounds such as bis(2,2,6,6-tetramethyl-4-piperidyl)-sebacate and phenothiazine.

The radical scavenger may also be of a commercially available product and examples thereof include ADEKA STAB (registered trademark) AO-30, ADEKA STAB AO-330, ADEKA STAB AO-20, ADEKA STAB LA-77, ADEKA STAB LA-57, ADEKA STAB LA-67, ADEKA STAB LA-68 and ADEKA STAB LA-87 (all of which are manufactured by ADEKA Corporation, trade names); and IRGANOX (registered trademark) 1010, IRGANOX 1035, IRGANOX 1076, IRGANOX 1135, TINUVIN 111FDL, TINUVIN 123, TINUVIN 144, TINUVIN 152, TINUVIN 292 and TINUVIN 5100 (all of which are manufactured by BASF Japan Ltd.).

Examples of the antioxidant functioning as a peroxide decomposer include phosphorus-based compounds such as triphenyl phosphite and sulfur-based compounds such as pentaerythritol tetralauryl thiopropionate, dilauryl thiodipropionate and distearyl-3,3′-thiodipropionate. The peroxide decomposer may be of a commercially available product and examples thereof include ADEKA STAB TPP (manufactured by ADEKA Corporation), MARK AO-412S (manufactured by ADEKA Corporation) and SUMILIZER (registered trademark) TPS (manufactured by Sumitomo Chemical Company, Limited). These antioxidants may be used individually, or two or more thereof may be used in combination.

In the photosensitive composition of the present invention, in addition to an antioxidant(s), an ultraviolet absorber may be used as well.

Examples of such ultraviolet absorber include benzophenone derivatives, benzoate derivatives, benzotriazole derivatives, triazine derivatives, benzothiazole derivatives, cinnamate derivatives, anthranilate derivatives and dibenzoylmethane derivatives.

Examples of the benzophenone derivatives include 2-hydroxy-4-methoxybenzophenone, 2-hydroxy-4-n-octoxybenzophenone, 2,2′-dihydroxy-4-methoxybenzophenone and 2,4-dihydroxybenzophenone.

Examples of the benzoate derivatives include 2-ethylhexyl salicylate, phenyl salicylate, p-t-butylphenyl salicylate, 2,4-di-t-butylphenyl-3,5-di-t-butyl-4-hydroxybenzoate and hexadecyl-3,5-di-t-butyl-4-hydroxybenzoate.

Examples of the benzotriazole derivatives include 2-(2′-hydroxy-5′-t-butylphenyl)benzotriazole, 2-(2′-hydroxy-5′-methylphenyl)benzotriazole, 2-(2′-hydroxy-3′-t-butyl-5′-methylphenyl)-5-chlorobenzotriazole, 2-(2′-hydroxy-3′,5′-di-t-butylphenyl)-5-chlorobenzotriazole, 2-(2′-hydroxy-5′-methylphenyl)benzotriazole and 2-(2′-hydroxy-3′,5′-di-t-amylphenyl)benzotriazole.

Examples of the triazine derivatives include hydroxyphenyl triazine and bis-ethylhexyloxyphenol methoxyphenyl triazine.

The ultraviolet absorber may be of a commercially available product and examples thereof include TINUVIN PS, TINUVIN 99-2, TINUVIN 109, TINUVIN 384-2, TINUVIN 900, TINUVIN 928, TINUVIN 1130, TINUVIN 400, TINUVIN 405, TINUVIN 460 and TINUVIN 479 (all of which are manufactured by BASF Japan Ltd.). The above-described ultraviolet absorbers may be used individually, or two or more thereof may be used in combination. By using the ultraviolet absorber(s) in combination with an antioxidant, a cured product obtained from the photosensitive composition of the present invention can be stabilized.

In the photosensitive composition of the present invention, in order to further improve the flame retardancy, a known and commonly used flame retardant, examples of which include organic phosphorus flame retardants such as phosphorus compounds (e.g., metal phosphinates), phosphate and condensed phosphate, cyclic phosphazene compounds and phosphazene oligomers, may be incorporated as well.

In the photosensitive composition of the present invention, as required, a known additive(s), examples of which include: known thermal polymerization inhibitors; known thickening agents such as fine powder silica, organic bentonite and montmorillonite; antifoaming agents such as silicone-based, fluorine-based and polymeric antifoaming agents; leveling agents; silane coupling agents such as imidazole-based, thiazole-based and triazole-based silane coupling agents; antioxidants; and corrosion inhibitors, may further be incorporated.

A thermal polymerization inhibitor can be used to inhibit thermal polymerization or polymerization with time of a polymerizable compound. Examples of the thermal polymerization inhibitor include 4-methoxyphenol, hydroquinone, alkyl- or aryl-substituted hydroquinone, t-butylcatechol, pyrogallol, 2-hydroxybenzophenone, 4-methoxy-2-hydroxybenzophenone, cuprous chloride, phenothiazine, chloranil, naphthylamine, β-naphthol, 2,6-di-t-butyl-4-cresol, 2,2′-methylenebis(4-methyl-6-t-butylphenol), pyridine, nitrobenzene, dinitrobenzene, picric acid, 4-toluidine, methylene blue, a reaction product between copper and an organic chelating agent, methyl salicylate and a chelate between phenothiazine, a nitroso compound or a nitroso compound and Al.

In the photosensitive composition of the present invention, an adhesion promoting agent may be used in order to improve the interlayer adhesion or adhesion between an insulating resin layer and a substrate. Examples of such adhesion promoting agent include benzoimidazole, benzoxazole, benzothiazole, 3-morpholinomethyl-1-phenyl-triazole-2-thione, 5-amino-3-morpholinomethyl-thiazole-2-thione, triazole, tetrazole, benzotriazole, carboxybenzotriazole, amino group-containing benzotriazole and silane coupling agents.

The photosensitive composition of the present invention constituted in the above-described manner is, after being prepared to have a prescribed composition, for example, adjusted with an organic solvent to have a viscosity suitable for a coating method and then applied onto a substrate by a dip coating method, a flow coating method, a roll coating method, a bar coater method, a screen printing method, a curtain coating method or the like. Thereafter, the organic solvent contained in the composition is dried by evaporation (predrying) at a temperature of about 60 to 100° C. to form a tack-free coating film (insulating resin layer) can be formed. Here, the drying by evaporation can be carried out using a hot-air circulation-type drying oven, an IR oven, a hot plate, a convection oven or the like (a method in which a dryer equipped with a heat source utilizing a steam air-heating system is employed to bring a hot air inside the dryer into contact against the composition or a method in which a hot air is blown against the substrate via a nozzle).

In addition, an insulating resin layer may also be formed by preparing a dry film from the photosensitive composition and then laminating the thus obtained dry film on a substrate. The dry film has a structure in which, for example, a carrier film such as a polyethylene terephthalate (PET) film, an insulating resin layer such as a solder resist layer and a detachable cover film used as required are laminated in this order.

The insulating resin layer is a layer obtained by coating and drying the photosensitive composition on a carrier film or a cover film. Such an insulating resin layer is formed by uniformly coating a carrier film with the photosensitive composition according to this embodiment at a thickness of 10 to 150 μm using a blade coater, a lip coater, a comma coater, a film coater or the like and then drying the thus coated photosensitive composition. Further, as required, a cover film is laminated thereon to form a dry film. In this case, a carrier film may be laminated as well after coating and drying the photosensitive composition on the cover film.

As the carrier film, for example, a thermoplastic film of 2 to 150 μm in thickness, such as a polyester film, may be employed.

As the cover film, for example, a polyethylene film or a polypropylene film can be employed, and the adhesive force between the cover film and a solder resist layer is preferably smaller than that between the carrier film and the solder resist layer.

In cases where such a dry film is used, after removing the cover film, an insulating resin layer and a substrate are superimposed with each other and laminated using a laminator or the like, thereby the insulating resin layer is formed on the substrate. The carrier film may be detached before or after the below-described exposure step.

Here, examples of the substrate on which a coating film is formed or a dry film is laminated include copper-clad laminates of all grades (e.g., FR-4) such as copper-clad laminates for high-frequency circuit that are composed of a material such as paper phenol, paper epoxy, glass fabric epoxy, glass polyimide, glass fabric/nonwoven epoxy, glass fabric/paper epoxy, synthetic fiber epoxy, fluorine-polyethylene-polyphenylene ether or polyphenylene oxide-cyanate ester; other polyimide films; PET films; glass substrates; ceramic substrates; and wafer plates.

Further, the resulting laminate is selectively exposed to an active energy beam through a patterned photomask by a contact method (or a non-contact method) or directly exposed to a pattern using a laser-direct exposure apparatus. Consequently, the exposed parts (the parts irradiated with the active energy beam) of the coating film are cured.

As an exposure apparatus for performing the irradiation with an active energy beam, a direct imaging apparatus (for example, a laser-direct imaging apparatus which directly draws an image using a laser based on CAD data transmitted from a computer), an exposure apparatus equipped with a metal halide lamp, an exposure apparatus equipped with an (ultra)high-pressure mercury lamp, an exposure apparatus equipped with a mercury short arc lamp or a direct imaging apparatus utilizing an ultraviolet lamp such as an (ultra)high-pressure mercury lamp can be employed.

As the active energy beam, it is preferred to use a laser light having a maximum wavelength in the range of 350 to 410 nm. By using a laser light having a maximum wavelength in this range, radicals can be efficiently generated from the photopolymerization initiator. As long as the laser light has a maximum wavelength in this range, it may be either a gas laser or a solid-state laser. Further, although the exposure does is variable depending on the film thickness and the like, it may be set in the range of generally 5 to 500 mJ/cm², preferably 10 to 300 mJ/cm².

As a direct imaging apparatus, for example, those that are manufactured by Orbotech Japan Co., Ltd. and PENTAX RICOH IMAGING CO., LTD. can be employed, and any apparatus may be employed as long as it oscillates a laser light having a maximum wavelength of 350 to 410 nm.

After curing the exposed parts (the parts irradiated with the active energy beam) by exposing the coating film with light in this manner, the non-exposed parts are developed with a dilute aqueous alkaline solution (for example, 0.3 to 3% by wt aqueous sodium carbonate solution) to form a pattern on the resulting cured coating film.

In this process, as a developing method, for example, a dipping method, a shower method, a spray method or a brushing method may be employed. Further, as a developer, an aqueous alkaline solution of potassium hydroxide, sodium hydroxide, sodium carbonate, potassium carbonate, sodium phosphate, sodium silicate, ammonia, amine or the like may be employed.

Further, in cases where a thermosetting′component is added, for example, by heat-curing the composition at a temperature of about 140 to 180° C., a reaction is induced between the carboxylic group of the carboxyl group-containing resin and the thermosetting component having, for example, a plurality of cyclic ether groups and/or cyclic thioether groups in the molecule, so that a cured product (pattern) which is excellent in a variety of characteristics such as heat resistance, chemical resistance, resistance to moisture absorption, adhesion and electrical characteristics can be formed.

As described in the above, the photosensitive composition of the present invention can yield a coating film having a high sensitivity and excellent characteristics; therefore, the photosensitive composition can be advantageously used as a plating resist or solder resist of a printed wiring board. Especially, since even a thick layer of the photosensitive composition shows sufficient depth curability when exposed to a light and a very finely patterned resist film having a thickness of not less than 100 μm, a minimum line of 75 μm, a minimum space of 75 μm and a high aspect ratio can be formed, the photosensitive composition of the present invention can be suitably used particularly in the below-described method of producing a printed wiring board.

A preferred method of producing a printed wiring board where the photosensitive composition of the present invention is used will now be described concretely with reference to the appended drawings.

First, a substrate having a photosensitive resist film formed on the surface is prepared. The photosensitive composition of the present invention used in the formation of the photosensitive resist film may take the form of a dry film in which a dry coating film is formed on a carrier film or may be in the form of a liquid diluted with a solvent. When the photosensitive composition is in the form of a dry film, the dry film is laminated onto a substrate using a hot roll-type laminator or a vacuum laminator in the temperature range of about 40 to 130° C. and, when the photosensitive composition is in the form of a liquid, the liquid is applied onto a substrate by screen printing or using a spray coater, a die coater, a slit coater, a curtain coater, a roll coater or the like. Then, the resultant is dried in a hot-air circulation-type drying oven or a far-infrared drying oven at a temperature of about 60 to 150° C. for about 1 to 30 minutes to evaporate the solvent (predrying), thereby a tack-free photosensitive resist film can be formed. In this case, it is preferred that the thus formed photosensitive resist film have a thickness of about 100 μm or more. In order to form a flat surface with fine irregularities and to thereby improve the adhesion with the photosensitive resist film, the surface of the substrate may also be subjected to a known roughening treatment, for example, a swelling treatment with an alkaline solution such as an aqueous sodium hydroxide solution, a treatment with a liquid containing an oxidizing agent such as permanganate, bichromate, ozone, hydrogen peroxide/sulfuric acid or nitric acid, and/or a series of chemical treatments with acids such as an aqueous sulfuric acid solution, an aqueous hydrochloric acid solution and the like (treatments with oxidizing agents). In such roughening treatment, a commercially available desmear solution (roughening agent) may be used as well.

The film used in the dry film preparation is preferably a thermoplastic resin film made of polyethylene terephthalate or the like and the thickness thereof may be in the range of 10 to 50 μm. However, for easier handling, the film thickness is preferably 25 to 50 μm and, for attaining good resolution, the film thickness is preferably 10 to 25 μm. A dry film which is, in order to eliminate this difference, designed such that the photosensitive resist film has a refractive index of preferably not less than 1.5, more preferably 1.55 to 1.6, is preferred since good resolution can be attained even when a thicker carrier film is used.

### (1) Step of Forming Patterned Resist Film

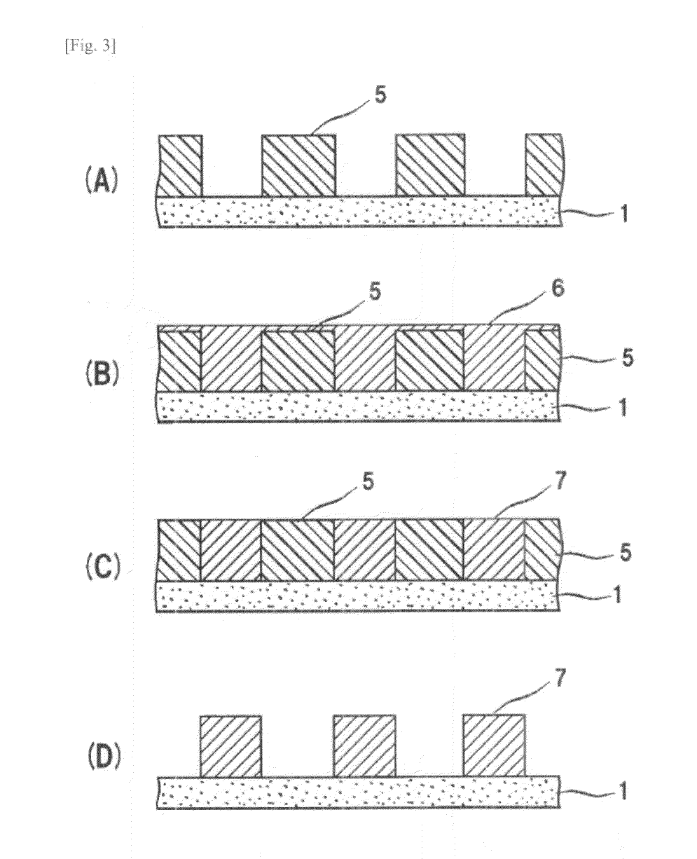

After boring a substrate 1, on which a photosensitive resist film is formed, to make a through-hole(s) as required, by performing selective exposure and development and then removing the resulting non-exposed parts, a patterned resist film 5 (hereinafter, simply referred to as “resist film” or “resist pattern”), on which a groove pattern is formed in the part where a circuit is to be formed and a copper plating layer can be formed by electroless copper plating, is prepared as shown in FIG. 3(A). It is noted here that, although FIG. 3(A) shows the substrate 1 having the resist film 5 formed on one side, the resist film may be formed on both sides of the substrate. Further, in cases where the photosensitive composition used in the formation of the photosensitive resist film contains a thermosetting component, by further heat-curing the resulting resist film, the properties thereof, such as heat resistance, chemical resistance, resistance to moisture absorption, adhesion and electric characteristics, can be improved.

(2) Electroless Copper Plating—Electrolytic Copper Plating Step

As shown in FIG. 3(B), the exposed surface of the above-described groove pattern part of the substrate 1 and the entire surface of the resist pattern 5 are subjected to electroless copper plating in accordance with a known method. Then, the resultant is subjected to electrolytic copper plating until the plated surface becomes substantially smooth, thereby forming a copper plating layer 6 which covers the above-described resist pattern 5.

In this case, prior to performing electroless copper plating, as a pretreatment for forming an electroless copper plating on the surface of the resist pattern 5, it is preferred that the developed resist pattern 5 be subjected to irradiation with an ultraviolet light stronger than the one used in the exposure process, heating at a temperature of not lower than the glass transition temperature (Tg) of the resist film, or a plasma treatment with argon, oxygen or the like. By performing such a pretreatment, not only electroless copper plating is deposited on the resist pattern 5, but also, for example, the amount of elution is reduced, so that contamination of plating solution can be inhibited and the plating can be deposited without any discoloration of the plated surface, defective gloss and pin-hole. Furthermore, the alkali resistance and swelling of the resist film are also suppressed, so that the shape of the formed circuit is stabilized as well.

In electroless copper plating, generally, a palladium catalyst is provided on the exposed surface of the substrate and the entire surface of the patterned resist film and the resultant is then immersed in an electroless copper plating solution to form a copper layer. It is generally appropriate that the thickness of the resulting electroless copper plating layer be in the range of about 0.5 to 2 μm. Further, as required, the thus formed electroless copper plating layer is subjected to a heat treatment at 100° C. to 200° C. The heating time is not particularly restricted; however, it is preferably selected to be 30 minutes to 5 hours. In order to inhibit oxidation of the copper foil, it is preferred that the heating be performed in vacuum or in an inert gas. Thereafter, the resultant is immersed in an electrolytic copper plating solution until the resist pattern 5 is coated and the surface of the copper plating layer 6 becomes substantially smooth as shown in FIG. 3(B), thereby forming an electrolytic copper plating layer. The thickness of the electrolytic copper plating layer can be arbitrarily selected.

### (3) Etching Step

After forming the copper plating layer 6 as shown in FIG. 3(B), the copper plating layer 6 is uniformly reduced by mechanical and/or chemical polishing or etching until the surface of the above-described resist pattern 5 is exposed as shown in FIG. 3(C), thereby exposing a copper circuit pattern 7 at the surface. For the mechanical and/or chemical polishing, a conventionally known method can be used.

### (4) Resist Film Detachment Step

The resist pattern 5 embedded between the copper circuit pattern 7s may be left intact as an insulating layer without being detached; however, as required, the resist pattern 5 alone may be swollen and detached with an aqueous alkaline solution, a solvent or the like and/or removed by a so-called desmear treatment with alkaline permanganate or the like, thereby a wiring board in which only the copper circuit pattern 7 is formed on the substrate 1 can be produced as shown in FIG. 3(D).

### (5) Step of Forming Interlayer Insulating Resin Layer

In cases where a multi-layer printed wiring board is further prepared, on the surface of the substrate having the resist pattern 5 and the copper circuit pattern 7 as shown in FIG. 3(C) or the surface of the substrate having only the copper circuit patter 7 as shown in FIG. 3(D), one or more resin compositions (e.g., an epoxy resin, a polyimide resin, a cyanate ester resin, a maleimide resin, a double bond-added polyphenylene ether resin and/or a bromine- or phosphorus-containing compound of these resins) is/are coated along with, as required, a thermosetting resin composition in which a known catalyst, a curing agent, a curing promoter or the like is incorporated and the coated material(s) is/are subsequently heat-cured, or a semi-solid prepreg obtained by impregnating a nonwoven fabric, a woven cloth or the like with a thermosetting resin composition and then partially curing the resultant is laminated or a film-form resin is laminated by thermo-compression bonding, thereby forming an interlayer insulating resin layer. The surface of the thus obtained interlayer insulating resin layer is, as required, subjected to the above-described roughening treatment. Alternatively, an interlayer insulating resin layer can be formed by: on the surface of the above-described substrate, coating a photosensitive composition containing the above-described thermosetting component and filler or laminating a dry film of the photosensitive composition; photo-curing the entirety of the thus coated photosensitive composition or the laminated dry film by irradiation with an active energy beam; and then further heat-curing the resultant by heating.

### (6) Step of Forming Resist Pattern

On the substrate on which an interlayer insulating resin layer is thus formed in the above-described manner, a photosensitive resist film is formed in the above-described manner and, as required, a via-hole(s) is/are made. Then, in the same manner as in the above-described step (1), the thus formed photosensitive resist film is subjected to selective exposure and development to form an outer layer resist pattern on which a groove pattern is formed in the part where a circuit is to be formed and a copper plating layer can be formed by electroless copper plating. In cases where the photosensitive composition used in the formation of the photosensitive resist film contains a thermosetting component, by further heat-curing the resulting resist film by heating it at a temperature of, for example, about 140 to 180° C., the carboxyl group of the above-described carboxyl group-containing resin and the thermosetting component having at least two cyclic (thio)ether groups in the molecule are allowed to react with each other, so that a cured coating film which is excellent in a variety of characteristics such as heat resistance, chemical resistance, resistance to moisture absorption, adhesion and electrical characteristics can be formed. Here, even when the photosensitive composition contains no thermosetting component, by subjecting the resulting resist film to a heat treatment, the ethylenically unsaturated bonds of the photocurable component remaining unreacted after the exposure undergo thermal radical polymerization and the properties of the coating film are thus improved; therefore, depending on the purpose and application, the resist film may be subjected to a heat treatment (heat-curing).

### (7) Electroless Copper Plating—Electrolytic Copper Plating Step

Then, in the same manner as in the above-described step (2), the exposed surface of the above-described interlayer insulating resin layer and the resist pattern surface were entirely subjected to electroless copper plating and then electrolytic copper plating until the plated surface becomes substantially smooth, thereby a copper plating layer of the outer layer which covers the above-described resist pattern is formed.

### (8) Etching Step

After forming the copper plating layer of the outer layer in the above-described manner, the thus obtained copper plating layer is, in the same manner as in the above-described step (3), uniformly reduced by mechanical and/or chemical polishing or etching until the surface of the above-described resist pattern is exposed, thereby exposing a copper circuit pattern of the outer layer at the surface. The resist pattern embedded between the copper circuit patterns may be left intact as an insulating layer without being detached; however, as required, the resist pattern alone may be swollen and detached with an aqueous alkaline solution, a solvent or the like and/or removed by a so-called desmear treatment with alkaline permanganate or the like, thereby a wiring board in which only the copper circuit pattern of the outer layer is formed in the surface layer part can be produced.

A multi-layer printed wiring board having more layers can be produced with good productivity by repeating the above-described steps (5) to (8). In a circuit pattern formed by the above-described method, no electric conductor exists between the circuit patterns even when the line-and-space is narrower than 75 μm; therefore, the circuit has excellent insulation reliability.

### EXAMPLES

The present invention will now be described concretely by way of examples and comparative examples thereof; however, the present invention is not restricted to the following examples by any means. It is noted here that, in the following Examples and Comparative Example, “part(s)” and “%” are all based on the mass unless otherwise specified.

### Synthesis Example 1

To a four-necked flask equipped with a stirrer and a reflux condenser, 220 parts (1 equivalent) of a cresol novolac-type epoxy resin, EPICLON N-695 (manufactured by DIC Corporation, epoxy equivalent=220) was loaded, 216 parts of carbitol acetate was added thereto, and the resulting mixture was dissolved by heating. Then, 0.46 part of methylhydroquinone and 1.38 parts of triphenyl phosphine were further added as a polymerization inhibitor and a reaction catalyst, respectively. This mixture was heated to 95 to 105° C., 57.6 parts (0.8 equivalent) of acrylic acid and 34 parts (0.2 equivalent) of p-phenylphenol were slowly added thereto dropwise, and the resultant was allowed to react for 16 hours. The resulting reaction product (hydroxyl group: 1 equivalent) was cooled to 80 to 90° C. and 87 parts (0.56 equivalent) of tetrahydrophthalic anhydride was added. The resultant was allowed to react for 8 hours and then cooled before being recovered. The thus obtained carboxyl group-containing photosensitive resin had a non-volatile content of 65% and a solid acid value of 80 mg KOH/g. Hereinafter, this reaction solution is referred to as “A-1 varnish”.

### Preparation of Photosensitive Resist Composition:

The respective components shown in Tables 1 to 3 below were blended at the ratios (parts by mass) shown in Tables 1 to 3. The resultants were each pre-mixed using a stirrer and then kneaded with a 3-roll mill to prepare the respective photosensitive resist compositions.

TABLE 1

| | | Photosensitive resist | | | | | |
|---|---|---|---|---|---|---|---|
| Composition (parts by mass) | | A | B | C | D | E | F |
| Photosensitive resin*¹ | | 161 | 161 | 161 | 161 | 161 | 161 |
| Photosensitive monomer*² | | 20 | 20 | 20 | 20 | 20 | 20 |
| Photopolymerization initiator*³ | | 2.5 | 2.5 | 2.5 | 2.5 | 2.5 | 2.5 |
| Polymerization inhibitor*⁴ | | 0.1 | 0.1 | 0.1 | 0.1 | 0.1 | 0.1 |
| Thermosetting resin*⁵ | | 33 | 33 | 33 | 33 | 33 | 33 |
| Inorganic filler-1*⁶ | | 100 | | | | | 80 |
| Inorganic filler-2*⁷ | | | 100 | | | | |
| Inorganic filler-3*⁸ | | | | 100 | | | |
| Inorganic filler-4*⁹ | | | | | 100 | | |
| Inorganic filler-5*¹⁰ | | | | | | 100 | |
| Inorganic filler-6*¹¹ | | | | | | | 10 |
| Inorganic filler-7*¹² | | | | | | | 10 |
| Phosphorus compound*¹³ | | 15 | 15 | 15 | 15 | 15 | 15 |
| Heat-curing catalyst*¹⁴ | | 0.5 | 0.5 | 0.5 | 0.5 | 0.5 | 0.5 |
| Absorbance per 25 μm | 365 nm | 0.012 | 0.012 | 0.012 | 0.011 | 0.012 | 0.013 |
| | 405 nm | 0.01> | 0.01> | 0.01> | 0.01> | 0.01> | 0.01> |

Note
*¹A-1 varnish
*²DPHA (dipentaerythritol hexaacrylate, manufactured by Nippon Kayaku Co., Ltd.)
*³IRGACURE 127 (alkylphenone-based photopolymerization initiator, manufactured by BASF Japan Ltd., bifunctional photopolymerization initiator)
*⁴phenothiazine (polymerization inhibitor, manufactured by Seiko Chemical Co., Ltd.)
*⁵NC-3000 (biphenyl novolac epoxy resin, manufactured by Nippon Kayaku Co., Ltd.), carbitol acetate cut (solid content = 75%)
*⁶HIGILITE (registered trademark) H42 (gibbsite-type aluminum hydroxide, manufactured by Showa Denko K.K., refractive index = 1.54)
*⁷KISUMA 5J (magnesium hydroxide, manufactured by Kyowa Chemical Industry Co., Ltd., refractive index = 1.56 to 1.58)
*⁸SILLITIN Z86 (SILLITIN, manufactured by Hoffmann Mineral GmbH, refractive index = 1.55)
*⁹DHT-4A (hydrotalcite, manufactured by Kyowa Chemical Industry Co., Ltd., refractive index = 1.50)
*¹⁰LMP-100 (talc, manufactured by Fuji Talc Industrial Co., Ltd., refractive index = 1.54 to 1.59)
*¹¹B-30 (barium sulfate, manufactured by Sakai Chemical Industry Co., Ltd., refractive index = 1.64)
*¹²APYRAL AOH 20 (boehmite-type aluminum hydroxide, manufactured by Nabaltec AG, refractive index = 1.62)
*¹³SPE-100 (cyclophenoxyphosphazene, manufactured by Otsuka Chemical Co., Ltd.)
*¹⁴1B2PZ (imidazole compound, manufactured by Shikoku Chemicals Corporation)

TABLE 2

| Composition | | Photosensitive resist | | | | |
|---|---|---|---|---|---|---|
| (parts by mass) | | G | H | I | J | K |
| Photosensitive | | 161 | 107 | 107 | 107 | |
| resin-1*¹ | | | | | | |
| Photosensitive | | | | 53 | | |
| resin-2*² | | | | | | |
| Photosensitive | | | | | 51 | |
| resin-3*³ | | | | | | |
| Photosensitive | | | | | | 46 |
| resin-4*⁴ | | | | | | |
| Photosensitive | | | | | | 213 |
| resin-5*⁵ | | | | | | |
| Photosensitive | | 20 | 20 | 20 | 20 | 20 |
| monomer*⁶ | | | | | | |
| Photopolymerization | | 2.5 | 2.5 | 2.5 | 2.5 | 2.5 |
| initiator-1*⁷ | | | | | | |
| Photopolymerization | | 0.6 | | | | |
| initiator-2*⁸ | | | | | | |
| Polymerization | | 0.1 | 0.1 | 0.1 | 0.1 | 0.1 |
| inhibitor*⁹ | | | | | | |
| Thermosetting resin*¹⁰ | | 33 | 33 | 33 | 33 | 33 |
| Inorganic filler-1*¹¹ | | 100 | 100 | 100 | 100 | 100 |
| Phosphorus | | 15 | 15 | 15 | 15 | 15 |
| compound*¹² | | | | | | |
| Heat-curing catalyst*¹³ | | 0.5 | 0.5 | 0.5 | 0.5 | 0.5 |
| Absorbance | 365 nm | 0.027 | 0.012 | 0.012 | 0.012 | 0.012 |
| per 25 μm | 405 nm | 0.015 | 0.01> | 0.01> | 0.01> | 0.01> |

Note
*¹A-1 varnish
*²ZFR-1124 (photosensitive resin, manufactured by Nippon Kayaku Co., Ltd.)
*³ZCR-1061 (photosensitive resin, manufactured by Nippon Kayaku Co., Ltd.)
*⁴JONCRYL-68 (photosensitive resin, manufactured by BASF Japan Ltd.) diluted with diethylene glycol monoethyl ether acetate (solid content = 72%)
*⁵CYCLOMER P(ACA) 300 (unsaturated group-containing acrylic resin mixture,manufactured by Daicel Corporation)
*⁶DPHA (dipentaerythritol hexaacrylate, manufactured by Nippon Kayaku Co., Ltd.)
*⁷IRGACURE 127 (alkylphenone-based photopolymerization initiator, manufactured by BASF Japan Ltd., bifunctional photopolymerization initiator)
*⁸TPO (acylphosphine oxide-based photopolymerization initiator, manufactured by BASF Japan Ltd.)
*⁹phenothiazine (polymerization inhibitor, manufactured by Seiko Chemical Co.,Ltd.)
*¹⁰NC-3000(biphenyl novolac epoxy resin; manufactured by Nippon Kayaku Co.,Ltd.), carbitol acetate cut (solid content = 75%)
*¹¹HIGILITE (registered trademark) H42 (gibbsite-type aluminum hydroxide,manufactured by Showa Denko K.K., refractive index = 1.54)
*¹²SPE-100 (cyclophenoxyphosphazene, manufactured by Otsuka Chemical Co.,Ltd.)
*¹³1B2PZ (imidazole compound, manufactured by Shikoku Chemicals Corporation)

TABLE 3

| Composition | | Photosensitive resist | | | | |
|---|---|---|---|---|---|---|
| (parts by mass) | | L | M | N | O | P |
| Photosensitive resin*¹ | | 161 | 161 | 161 | 161 | 161 |
| Photosensitive | | 20 | 20 | 20 | 20 | 20 |
| monomer*² | | | | | | |
| Photopolymerization | | 2.5 | | 2.5 | 2.5 | |
| initiator-1*³ | | | | | | |
| Photopolymerization | | | | | | 0.6 |
| initiator-2*⁴ | | | | | | |
| Photopolymerization | | | | | | 2.5 |
| initiator-3*⁵ | | | | | | |
| Photopolymerization | | | 0.07 | | | |
| initiator-4*⁶ | | | | | | |
| Polymerization | | 0.1 | 0.1 | 0.1 | 0.1 | 0.1 |
| inhibitor*⁷ | | | | | | |
| Thermosetting resin*⁸ | | | | 33 | 33 | 33 |
| Inorganic filler-1*⁹ | | 100 | 100 | | | 100 |
| Inorganic filler-2*¹⁰ | | | | 100 | | |
| Inorganic filler-3*¹¹ | | | | | 100 | |
| Phosphorus | | | | 15 | 15 | 15 |
| compound*¹² | | | | | | |
| Heat-curing catalyst*¹³ | | 0.5 | 0.5 | 0.5 | 0.5 | 0.5 |
| Absorbance | 365 nm | 0.018 | 0.024 | 0.012 | 0.012 | 0.563 |
| per 25 μm | 405 nm | 0.01> | 0.01> | 0.01> | 0.01> | 0.281 |

Note
*¹A-1 varnish
*²DPHA (dipentaerythritol hexaacrylate, manufactured by Nippon Kayaku Co., Ltd.)
*³IRGACURE 127 (alkylphenone-based photopolymerization initiator, manufactured by BASF Japan Ltd., bifunctional photopolymerization initiator)
*⁴TPO (acylphosphine oxide-based photopolymerization initiator, manufactured by BASF Japan Ltd.)
*⁵DETX-S (thioxanthone-based photopolymerization initiator, manufactured by Nippon Kayaku Co., Ltd.)
*⁶IRGACURE 389 (photopolymerization initiator, manufactured by BASF Japan Ltd.)
*⁷phenothiazine (polymerization inhibitor, manufactured by Seiko Chemical Co., Ltd.)
*⁸NC-3000 (biphenyl novolac epoxy resin, manufactured by Nippon Kayaku Co., Ltd.), carbitol acetate cut (solid content = 75%)
*⁹HIGILITE H42 (gibbsite-type aluminum hydroxide, manufactured by Showa Denko K.K., refractive index = 1.54)
*¹⁰BS-304N (silica, manufactured by Shionogi & Co., Ltd., refractive index = 1.43)
*¹¹SATINTONE 5(calcined kaolin, manufactured by Takehara Kagaku Kogyo Co., Ltd., refractive index = 1.62)
*¹²SPE-100 (cyclophenoxyphosphazene, manufactured by Otsuka Chemical Co., Ltd.)
*¹³1B2PZ (imidazole compound, manufactured by Shikoku Chemicals Corporation)

The absorbance values shown in the above Tables 1 to 3 were measured as follows.

### <Absorbance Measurement Method>

The absorbance was measured using an ultraviolet-visible spectrophotometer (Ubest-V-570DS, manufactured by JASCO Corporation) and an integrating-sphere photometer (ISN-470, manufactured by JASCO Corporation).

After coating a test sample, which is a photosensitive resist composition, onto a glass plate using an applicator, the resulting glass plate was dried in a hot-air circulation-type drying oven at 80° C. for 30 minutes to prepare a dry coating film of the photosensitive resist composition on the glass plate.

Then, using the ultraviolet-visible spectrophotometer and the integrating-sphere photometer, the absorbance baseline was measured for the same glass plate as the one coated with the photosensitive resist composition at a wavelength of 500 to 300 nm. Meanwhile, the absorbance of the glass plate on which the dry coating film was formed was measured and the absorbance of the dry coating film itself was calculated based on the thus obtained baseline to determine the absorbance at an intended light wavelength (365 nm or 405 nm). In order to prevent variations in the absorbance due to varying coating film thickness, the coating operation using the applicator was performed at four different coating thicknesses to prepare a graph showing the relationship between the coating thickness and the absorbance at each wavelength (365 nm or 405 nm). From the approximate formula of the graph, the absorbance of 200 μm-thick dry coating film was determined and defined as the absorbance of the dry coating film of each photosensitive resist composition.

### Example 1

The photosensitive resist compositions A to K diluted with dipropylene glycol monomethyl ether to 400 dPa·s were each printed on a 1.6 mm-thick copper foil-etched substrate of glass epoxy (FR-4 substrate) and dried at 90° C. for 30 minutes, thereby obtaining substrates on which a resist having a dry film thickness of 300 μm or 400 μm was formed. Then, using an ultrahigh-pressure mercury lamp-equipped exposure apparatus (manufactured by ORC Manufacturing Co., Ltd.), a pattern having a minimum line-and-space of 300 μm was drawn on each of the thus obtained substrates at an ultraviolet exposure dose of 400 mJ/cm². Thereafter, the pattern was developed with 30° C., 1 wt % aqueous sodium carbonate solution at a spray pressure of 2 atm and washed with water twice, thereby obtaining substrates having a photosensitive resist pattern formed thereon. The thus obtained substrates were cured in a hot-air drying oven at 150° C. for 1 hour.

Next, on the entire surface of the thus obtained substrate having a 300 μm thick dry coating film, a copper layer of 0.5 μm in thickness was formed using an electroless copper plating solution (ATS ADDCOPPER CT, manufactured by Okuno Chemical Industries Co., Ltd.). After heating the resulting substrate in a furnace at 130° C. for 2 hours, a copper layer of 300 μm in thickness was formed by electrolytic copper plating. The substrate on which these copper layers were thus formed was evenly polished by buffing the copper foil until the resist surface was exposed, thereby obtaining a circuit substrate having a minimum line-and-space of 300 μm.

### Example 2

After subjecting each of the 300 μm-thick circuit substrates thus prepared with the photosensitive resists A to K in Example 1 to a CZ treatment using an apparatus manufactured by MEC COMPANY LTD., a prepreg (high-reliability glass epoxy multi-layer material R-1650C, manufactured by Panasonic Corporation) was pasted on both sides and the resultant was laminate-molded for 2 hours under heating conditions of 110° C.×30 minutes+180° C.×90 minutes, pressure conditions of 5 kgf/cm²×15 minutes+20 kgf/cm² and a vacuum degree of 30 mmHg or less. The thus obtained 4-layer laminate was irradiated with single shot of carbon dioxide laser (output=13 mJ) to form a blind via-hole of 60 μm in diameter. Then, the photosensitive resists A to K having a dry film thickness of 300 μm were prepared under the above-described conditions and a circuit was formed therefrom in the same manner as in Example 1 to obtain a 4-layer circuit substrate having a minimum line-and-space of 300 μm. After subjecting each of the 4-layer circuit substrates thus prepared with the photosensitive resists A to K to a CZ treatment using an apparatus manufactured by MEC COMPANY LTD., a solder resist PSR-4000 G23K (manufactured by Taiyo Ink Mfg. Co., Ltd.) was screen-printed thereon and dried in a hot-air circulation-type drying oven at 80° C. for 30 minutes. Subsequently, using a metal halide lamp-equipped exposure apparatus (manufactured by ORC Manufacturing Co., Ltd.), the resulting solder resist pattern was exposed at 300 mJ/cm², developed with 30° C., 1-wt % aqueous sodium carbonate solution at a spray pressure of 2 atm and washed with water twice, thereby obtaining substrates having a photosensitive resist pattern formed thereon. Thereafter, the thus obtained substrates were heat-cured in a hot-air drying oven at 150° C. for 1 hour to obtain circuit substrates having a solder resist formed thereon.

### Example 3

Substrates on which a resist having a dry film thickness of 300 μm or 400 μm was formed were obtained by performing the printing on the copper foil-etched substrate of glass epoxy (FR-4 substrate) and the subsequent drying in the same manner as in Example 1, except that the photosensitive resist composition was changed to a photosensitive resist composition L or M. Then, the thus obtained substrates were each exposed and developed in the same manner as described above to prepare substrates having a photosensitive resist pattern formed thereon. After UV-curing the thus obtained substrates using a high-pressure mercury lamp-equipped UV conveyor at 200 mJ/cm², the resulting substrates were each subjected to a plasma treatment with oxygen plasma of 500 W at 250 mTorr for 60 seconds. Subsequently, after forming a copper layer of 0.5 μm in thickness on the entire surfaces of the thus treated substrates using an electroless copper plating solution (ATS ADDCOPPER CT, manufactured by Okuno Chemical Industries Co., Ltd.) and drying the resulting substrates in a furnace at 130° C. for 2 hours, a copper layer of about 300 μm in thickness was formed by electrolytic copper plating. The substrates on which these copper layers were thus formed were each evenly polished by buffing the copper foil until the resist surface was exposed and the resist was detached using 60° C., 10 wt % NaOH aqueous solution, thereby obtaining substrates on which a copper circuit having a minimum line-and-space of 200 μm was formed. On each of the thus obtained substrates, a solder resist PSR-4000 G23K (manufactured by Taiyo Ink Mfg. Co., Ltd.) was screen-printed and dried in a hot-air circulation-type drying oven at 80° C. for 30 minutes. Subsequently, using a metal halide lamp-equipped exposure apparatus (manufactured by ORC Manufacturing Co., Ltd.), the resulting solder resist pattern was exposed at 300 mJ/cm², developed with 30° C., 1 wt % aqueous sodium carbonate solution at a spray pressure of 2 atm and washed with water twice, thereby obtaining substrates having a photosensitive resist pattern formed thereon. Thereafter, the thus obtained substrates were heat-cured in a hot-air drying oven at 150° C. for 1 hour to obtain circuit substrates having a solder resist formed thereon.

### Comparative Example 1

Circuit substrates having a copper thickness of 300 μm and a minimum line-and-space of 300 μm were obtained by performing the printing on the copper foil-etched substrate of glass epoxy (FR-4 substrate), the drying and the subsequent steps of exposure to buffing in the same manner as in Example 1, except that the photosensitive resist composition was changed to a photosensitive resist composition N, O or P.

The circuit substrates prepared in the above-described Examples and Comparative Example were subjected to the below-described characteristic tests. The results thereof are shown in Tables 4 to 8.

TABLE 4

| | Example 1 | | | | | |
|---|---|---|---|---|---|---|
| Photosensitive resist | A | B | C | D | E | F |
| Fine line-forming property at a dry film | ∘ | ∘ | ∘ | ∘ | ∘ | ∘ |
| thickness of 300 μm | | | | | | |
| Fine line-forming property at a dry film | ∘ | ∘ | ∘ | ∘ | ∘ | Δ |
| thickness of 400 μm | | | | | | |
| Flatness of circuit and insulating layer | ∘ | ∘ | ∘ | ∘ | ∘ | ∘ |
| Solder heat resistance | ∘ | ∘ | ∘ | ∘ | ∘ | ∘ |

TABLE 5

| | Example 1 | | | | |
|---|---|---|---|---|---|
| Photosensitive resist | G | H | I | J | K |
| Fine line-forming property at a dry film | ∘ | ∘ | ∘ | ∘ | ∘ |
| thickness of 300 μm | | | | | |
| Fine line-forming property at a dry film | ∘ | ∘ | ∘ | ∘ | Δ |
| thickness of 400 μm | | | | | |
| Flatness of circuit and insulating layer | ∘ | ∘ | ∘ | ∘ | ∘ |
| Solder heat resistance | ∘ | ∘ | ∘ | ∘ | ∘ |

TABLE 6

| | Example 2 | | | | | |
|---|---|---|---|---|---|---|
| Photosensitive resist | A | B | C | D | E | F |
| Fine line-forming property at a dry film | ∘ | ∘ | ∘ | ∘ | ∘ | ∘ |
| thickness of 300 μm | | | | | | |
| Fine line-forming property at a dry film | ∘ | ∘ | ∘ | ∘ | ∘ | Δ |
| thickness of 400 μm | | | | | | |
| Flatness of circuit and insulating layer | ∘ | ∘ | ∘ | ∘ | ∘ | ∘ |
| Solder heat resistance | ∘ | ∘ | ∘ | ∘ | ∘ | ∘ |

TABLE 7

| | Example 2 | | | | |
|---|---|---|---|---|---|
| Photosensitive resist | G | H | I | J | K |
| Fine line-forming property at a dry film | ∘ | ∘ | ∘ | ∘ | ∘ |
| thickness of 300 μm | | | | | |
| Fine line-forming property at a dry film | ∘ | ∘ | ∘ | ∘ | Δ |
| thickness of 400 μm | | | | | |
| Flatness of circuit and insulating layer | ∘ | ∘ | ∘ | ∘ | ∘ |
| Solder heat resistance | ∘ | ∘ | ∘ | ∘ | ∘ |

TABLE 8

| | Example | | Comparative | | |
|---|---|---|---|---|---|
| | 3 | | Example 1 | | |
| Photosensitive resist | L | M | N | O | P |
| Fine line-forming property at a dry film | ∘ | ∘ | x | x | x |
| thickness of 300 μm | | | | | |
| Fine line-forming property at a dry film | ∘ | ∘ | x | x | x |
| thickness of 400 μm | | | | | |
| Flatness of circuit and insulating layer | Δ | Δ | — | — | — |
| Solder heat resistance | — | — | — | — | — |

### (1) Fine Line-Forming Property

Whether or not a circuit of L/S (line/space)=300/300 urn (Example 3) was formed was verified under a microscope and evaluated based on the following criteria.

For those cases of the photosensitive resists L and M of Example 3, the evaluation was performed when a photosensitive resist pattern was formed on the respective substrates.

∘: The difference between the upper side width and the lower side width was within 10% of the designed value.

Δ: The difference between the upper side width and the lower side width was greater than 10% of the designed value.

x: Detachment was observed.

### (2) Flatness of Circuit and Insulating Layer

The flatness of the circuit and insulating layer was visually observed and evaluated based on the following criteria.

For those cases of the photosensitive resists L and M of Example 3, the evaluation was performed when a photosensitive resist pattern was formed on the respective substrates.

∘: No problem.

Δ: Irregularities were generated.

x: Irregularities were prominent and coating of the solder resist was difficult.

### (3) Solder Heat Resistance

After being coated with a rosin-based flux, the resulting substrate was dipped into a 288° C. solder liquid for 30 seconds, and the presence or absence of a defect was observed and evaluated based on the following criteria.

∘: No defect was observed after five 30-second dippings.

Δ: No defect was observed until three 30-second dippings.

x: Swelling and detachment were observed after three 30-second dippings.

As seen from the results shown in Tables 4 to 8, in those cases of the photosensitive resists A to E and G to J of Examples 1 and 2, since the groove pattern in the part where a circuit was prepared in advance was formed by each photosensitive resist as a permanent resist, the step of forming an insulating resin laminate was not necessary and it was able to obtain a very fine substrate in which an insulating material was sufficiently filled (embedded) between the copper circuits despite a large thickness of the copper circuits. Further, in the thus obtained wiring boards, the surfaces of the circuits and insulating layers were flat; therefore, the methods were found to be capable of forming a solder resist layer as well at a uniform thickness with high precision.

In the case of the photosensitive resist F of Examples 1 and 2, as compared to a conventional subtractive method, a substrate having superior circuit width accuracy was obtained; however, the substrate had a reduced copper circuit width. This reduction in the copper circuit width is believed to be attributable to an increase in the resist line thickness caused by scattering of the ultraviolet light during the exposure due to the effect of the filler having a refractive index largely different from that of the resin, which was contained in the resist in a small amount. Also in the case of the photosensitive resist K of Examples 1 and 2, as compared to a conventional subtractive method, a substrate having superior circuit width accuracy was obtained; however, the substrate had a reduced copper circuit width. This is believed to be attributable to scattering of the ultraviolet light during the exposure caused by the absence of aromatic ring in the structure of the carboxyl group-containing resin used in the photosensitive resist K and the difference between its refractive index and that of the inorganic filler.

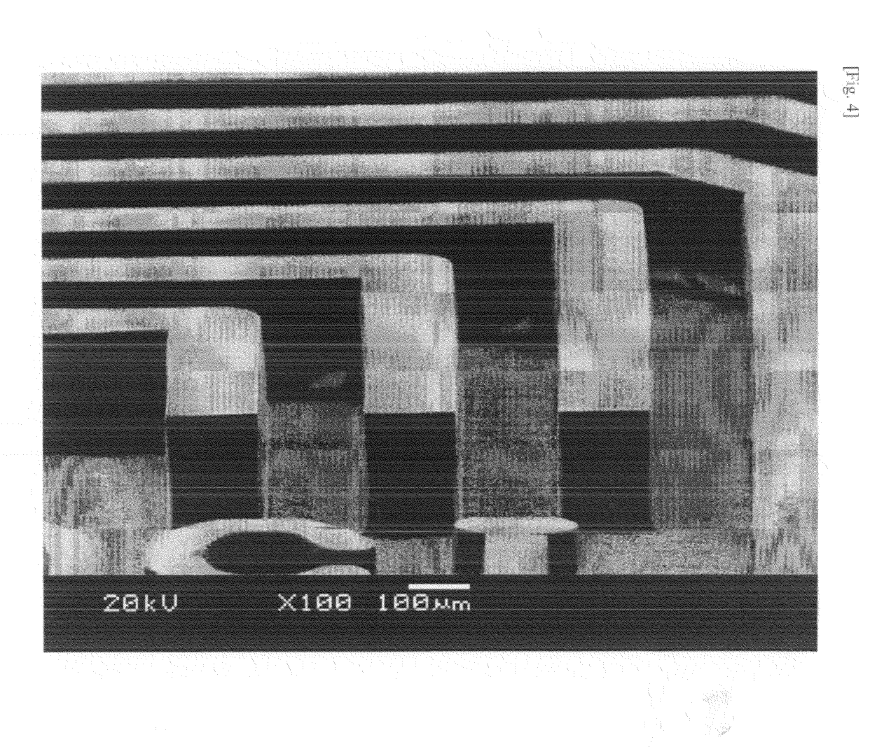

Furthermore, in the case of Example 3, as compared to a conventional subtractive method, substrates having superior circuit width accuracy were obtained; however, these substrates were not as flat as those of Examples 1 and 2 because the solder resist was coated after detaching the photosensitive resist pattern. FIG. 4 is an optical micrograph (magnification=×100) showing a condition in which only a fine copper circuit pattern was formed on a substrate after removal of the resist pattern prepared in the above-described Example 1 (condition shown in FIG. 3(D)).

In the cases of the photosensitive resists N and O used in Comparative Example 1, since an inorganic filler having a refractive index largely different from that of the resin was employed, the inorganic filler contained in the respective photosensitive resists easily caused irregular reflection of the ultraviolet light, so that a very fine photosensitive resist pattern could not be drawn. In the case of the photosensitive resist P, the photosensitive resist pattern was detached at the time of development, so that a copper circuit could not be obtained. This is believed to be because, since the absorbance of the photosensitive resist per thickness of 25 μm was too large at both wavelengths of 365 nm and 405 nm, the ultraviolet light was excessively absorbed by the photosensitive resist during the exposure and the ultraviolet light thus did not sufficiently reach the bottom portion of the photosensitive resist, so that a very fine resist pattern could not be drawn.

The refractive indices of the carboxyl group-containing resins used in the above-described photosensitive resists, which are CYCLOMER P(ACA) 300 (unsaturated group-containing acrylic resin mixture, manufactured by Daicel Corporation), JONCRYL-68 diluted with diethylene glycol monoethyl ether acetate, A-1 varnish, ZCR-1061 (photosensitive resin, manufactured by Nippon Kayaku Co., Ltd.) and ZFR-1124 (photosensitive resin, manufactured by Nippon Kayaku Co., Ltd.), and the refractive index of the diluting solvent were measured. Table 9 shows the values obtained by converting the thus measured refractive indices in terms of solid content of 100%.

TABLE 9

| | | Solid refractive |
|---|---|---|
| | Presence/absence | index |
| Carboxyl group-containing resin | of aromatic ring | (converted value) |
| CYCLOMER P(ACA) 300 | absent | 1.51 |
| JONCRYL-68 diluted with | present | 1.52 |
| diethylene glycol | | |
| monoethyl ether acetate | | |
| A-1 varnish | present | 1.56 |
| ZCR-1061 | present | 1.59 |
| ZFR-1124 | present | 1.56 |

As shown in Table 9, the refractive indices (solid refractive indices) of the carboxyl group-containing resins themselves generally fall in the range of 1.5 to 1.6. In the photosensitive composition according to the present invention, a filler having a refractive index of 1.5 to 1.6 is employed such that the filler has a refractive index identical or close to that of the carboxyl group-containing resin used in the photosensitive composition. It is believed that this enabled to inhibit halation during exposure and to attain a high resolution and sufficient depth curability.

### INDUSTRIAL APPLICABILITY

The photosensitive composition according to the present invention or a dry film thereof can be advantageously used as a plating resist or solder resist of a printed wiring board and is useful particularly in the formation of a very finely patterned resist film having a high aspect ratio.

### DESCRIPTION OF SYMBOLS

1, 101: Substrate (insulating substrate)
2: Copper foil
3: Copper-clad laminate
4: Photosensitive resist film
5: Resist pattern
6: Copper plating layer
7: Copper circuit pattern
8: Interlayer insulating resin layer
9: Via-hole
10: Outer layer resist pattern
11: copper plating layer of outer layer
12: Outer layer copper circuit pattern
102: Copper layer
103: Photosensitive resin layer
104: Copper circuit pattern
105: Solder resist film

1. A photosensitive composition, which comprises:
a carboxyl group-containing resin;
a photopolymerization initiator;
a photosensitive acrylate compound; and
a filler, having a refractive index of 1.5 to 1.6,
wherein a dry coating film comprising said photosensitive composition has at least one of an absorbance of 0.01 to 0.2 at a wavelength of 365 nm and an absorbance of 0.01 to 0.2 at a wavelength of 405 nm per thickness of 25 μm.

2. The photosensitive composition according to claim 1, wherein said filler contains at least one of Al and Mg.

3. The photosensitive composition according to claim 1, wherein said filler is included in an amount of 20 to 60 wt % with respect to a total amount of said photosensitive composition.

4. The photosensitive composition according to claim 1, wherein said photopolymerization initiator is an alkylphenone-based photopolymerization initiator.

5. A plating resist comprising:
the photosensitive composition according to claim 1.

6. A cured coating film produced by a process comprising: forming a layer comprising the photosensitive composition according to claim 1 on an insulating substrate; selectively exposing and developing said layer; and optionally performing heat-curing.

7. A printed wiring board, which comprises:
an insulating substrate having a surface;
a layer comprising the photosensitive composition according to claim 1 and being formed on the surface of said insulating substrate, the layer having a thickness of not less than 100 μm and a groove pattern which has a minimum line of 75 μm and a minimum space of 75 μm and is formed by selective exposure with a light and development; and
a wire circuit comprising copper and formed in said groove pattern of said layer, said wire circuit being formed such that the wire circuit has a surface forming substantially the same plane as a surface of said layer.

8. The photosensitive composition according to claim 2, wherein said filler is included in an amount of 20 to 60 wt % with respect to a total amount of said photosensitive composition.

9. The photosensitive composition according to claim 2, wherein said photopolymerization initiator is an alkylphenone-based photopolymerization initiator.

10. The photosensitive composition according to claim 3, wherein said photopolymerization initiator is an alkylphenone-based photopolymerization initiator.

11. A plating resist comprising:
the photosensitive composition according to claim 2.

12. A plating resist comprising:
the photosensitive composition according to claim 3.

13. A plating resist comprising:
the photosensitive composition according to claim 4.

14. A cured coating film produced by a process comprising: forming a layer comprising the photosensitive composition according to claim 2 on an insulating substrate; selectively exposing and developing said layer; and optionally performing heat-curing.

15. A cured coating film produced by a process comprising: forming a layer comprising the photosensitive composition according to claim 3 on an insulating substrate; selectively exposing and developing said layer; and optionally performing heat-curing.

16. A cured coating film produced by a process comprising: forming a layer comprising the photosensitive composition according to claim 4 on an insulating substrate; selectively exposing and developing said layer; and optionally performing heat-curing.

17. A printed wiring board, which comprises:
an insulating substrate having a surface;
a layer comprising the photosensitive composition according to claim 2 and being formed on the surface of said insulating substrate, the layer having a thickness of not less than 100 μm and a groove pattern which has a minimum line of 75 μm and a minimum space of 75 μm and is formed by selective exposure with a light and development; and
a wire circuit comprising copper and formed in said groove pattern of said layer, said wire circuit being formed such that the wire circuit has a surface forming substantially the same plane as a surface of said layer.

18. A printed wiring board, which comprises:
an insulating substrate having a surface;
a layer comprising the photosensitive composition according to claim 3 and being formed on the surface of said insulating substrate, the layer having a thickness of not less than 100 μm and a groove pattern which has a minimum line of 75 μm and a minimum space of 75 μm and is formed by selective exposure with a light and development; and
a wire circuit comprising copper and formed in said groove pattern of said layer, said wire circuit being formed such that the wire circuit has a surface forming substantially the same plane as a surface of said layer.

19. A printed wiring board, which comprises:
an insulating substrate having a surface;
a layer comprising the photosensitive composition according to claim 4 and being formed on the surface of said insulating substrate, the layer having a thickness of not less than 100 μm and a groove pattern which has a minimum line of 75 μm and a minimum space of 75 μm and is formed by selective exposure with a light and development; and
a wire circuit comprising copper and formed in said groove pattern of said layer, said wire circuit being formed such that the wire circuit has a surface forming substantially the same plane as a surface of said layer.
